(19) United States
(12) Patent Application Publication
(10) Pub. No.: US 2024/0387394 A1
(43) Pub. Date: Nov. 21, 2024

(54) SEMICONDUCTOR DEVICES AND METHODS OF MANUFACTURING THEREOF

(71) Applicant: Taiwan Semiconductor Manufacturing Company, Ltd., Hsinchu (TW)

(72) Inventors: Hung-Jen Hsu, Hsinchu City (TW); Fong-yuan Chang, Hsinchu County (TW); Shuo-Mao Chen, New Taipei City (TW)

(73) Assignee: Taiwan Semiconductor Manufacturing Company, Ltd., Hsinchu (TW)

(21) Appl. No.: 18/789,206

(22) Filed: Jul. 30, 2024

Related U.S. Application Data
(62) Division of application No. 17/586,664, filed on Jan. 27, 2022.
(60) Provisional application No. 63/275,236, filed on Nov. 3, 2021.

(51) Int. Cl. H01L 23/538; H01L 21/48; H01L 23/00; H01L 23/58; H01L 25/065

(52) U.S. Cl. CPC H01L 23/5389; H01L 21/4853; H01L 21/4857; H01L 23/5383; H01L 23/5386; H01L 23/585; H01L 24/19; H01L 24/20; H01L 25/0652; H01L 2224/214

(57) ABSTRACT

A semiconductor device includes a first semiconductor die. The semiconductor device includes a redistribution structure disposed over a first side of the first semiconductor die and comprising a plurality of layers. At least a first one of the plurality of layers comprises a first power/ground plane embedded in a dielectric material and configured to provide a first supply voltage for the first semiconductor die. The first power/ground plane encloses a plurality of first conductive structures that are each operatively coupled to the first semiconductor die, and a plurality of second conductive structures scattered around the plurality of first conductive structures.

### CROSS-REFERENCE TO RELATED APPLICATIONS

This application is a divisional application of U.S. patent application Ser. No. 17/586,664, filed Jan. 27, 2022, which claims priority to and the benefit of U.S. Provisional Application No. 63/275,236, filed Nov. 3, 2021, entitled “SEMICONDUCTOR STRUCTURE AND A FORMING METHOD THEREOF,” each of which is incorporated herein by reference in its entirety for all purposes.

### BACKGROUND

The semiconductor industry has experienced rapid growth due to continuous improvement in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-nanometer node), which allows more components to be integrated into a given area. As the demand for miniaturization, higher speed, and greater bandwidth, as well as lower power consumption and latency has grown recently, there has grown a need for smaller and more creative packaging techniques for semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of an example redistribution structure, in accordance with some embodiments.

FIGS. 2 and 3 respectively illustrate top views of one of the redistribution layers of the redistribution structure of FIG. 1, in accordance with some embodiments.

FIGS. 4, 5, 6, 7, 8, 9, 10, 11, 12, and 13 respectively illustrate top views of one of the redistribution layers of the redistribution structure of FIG. 1, in accordance with some embodiments.

FIG. 14 illustrates a flowchart of an example method to form at least a portion of a redistribution structure, as disclosed herein, in accordance with some embodiments.

FIGS. 15, 16, 17, 18, 19, 20, 21, 22, 23, and 24 respectively illustrate cross-sectional views of a portion of an example redistribution structure made by the method of FIG. 14, at various fabrication stages, in accordance with some embodiments.

FIG. 25 illustrates a cross-sectional view of a portion of a redistribution structure made by the method of FIG. 14, which includes a number of the disclosed redistribution layers, in accordance with some embodiments.

FIGS. 26, 27, 28, and 29 respectively illustrate various example packaged semiconductor devices including the disclosed redistribution structure, in accordance with some embodiments.

FIG. 30 illustrates a flowchart of a method of manufacturing a semiconductor device, in accordance with some embodiments.

FIG. 31 illustrates a block diagram of a system of generating an IC layout design, in accordance with some embodiments.

FIG. 32 illustrates a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As semiconductor technologies further advance, packaged semiconductor devices, e.g., three dimensional integrated circuits (3DICs), have emerged as an effective alternative to further reduce the physical size of semiconductor devices. In a packaged (e.g., stacked) semiconductor device, active circuits such as logic, memory, processor circuits, and the like are fabricated on different semiconductor wafers or dies. Two or more these semiconductor dies may be installed side-by-side or stacked on top of one another to further reduce the form factor of the semiconductor device.

To form such a packaged semiconductor device including a number of semiconductor dies, a redistribution structure electrically coupled to those semiconductor dies is typically used. In general, the redistribution structure of a packaged semiconductor device is configured to allow connectors (e.g., input/output pads) of a semiconductor die available in other locations of the packaged semiconductor device, e.g., for better access to the connectors where necessary. Such a redistribution structure typically includes a number of redistribution layers stacked on top of one another. Each of the redistribution layers, embedded in a dielectric material, includes a number of conductive structures electrically coupled to neighboring redistribution layer(s). One or more of the conductive structures are configured to provide supply voltage to one or more corresponding semiconductor die(s), which are sometimes referred to as a power/ground plane, and some of the conductive structures are configured to carry signals to and/or from the corresponding semiconductor die(s), which are sometimes referred to as signal routing paths.

In the existing technologies, the power/ground plane is typically formed as a plane occupying a relatively large portion of the area of a corresponding redistribution layer, with the signal routing paths each disposed within a relatively tight spacing (e.g., about 10 micrometers (μm)) within the large plane. In this way, a total resistance and a total area of the packaged semiconductor device may be reduced. However, such a tight spacing can result in undesired (e.g., parasitic) capacitances and/or inductances. These undesired capacitances and/or inductances may disadvantageously impact various transmission performance (e.g., scattering parameters) of the redistribution structure, and in turn the packaged semiconductor device as a whole, e.g., when the signals transmitted over those signal routing paths in a relatively high frequency. Thus, the existing packaged semiconductor device has not been entirely satisfactory in many aspects.

The present disclosure provides various embodiments of a redistribution structure that resolves the above-identified issues. In various embodiments, each redistribution layer of the redistribution structure, as disclosed herein, allows its corresponding signal routing paths to be spaced from one another with a relatively large spacing, while keeping a total area of the redistribution layer small. For example, the redistribution layer includes a number of polka dot-like structures scattered around each of the signal routing paths. These polka dot-like structures are electrically floating (i.e., electrically disconnected from any supply voltage). By forming such floating dot structures around the signal routing paths, the signal routing paths can be allowed to be spaced from one another with a relatively large spacing (e.g., about 20 μm or greater), while meeting various design rules (e.g., Electrical Rule Checking (ERC), Design Rule Checking (DRC)) in the advanced technology nodes. As such, even if signals are transmitted over the signal routing paths in a high frequency (e.g., from hundreds of megahertz to hundreds of gigahertz), various scattering parameters-related properties (e.g., insertion loss, return loss) of the redistribution structure can be improved or at least unaffected. Further, the disclosed redistribution structure can optionally include a guard ring structure enclosing the signal routing paths (and the floating dot structures) from the power/ground plane, and one or more power/ground reference structures disposed between the signal routing paths, in various embodiments. With such guard ring and/or power/ground reference structures, cross-talk among the signal routing paths can be significantly suppressed, which can further enhance the overall performance of a packaged semiconductor device implementing the redistribution structure.

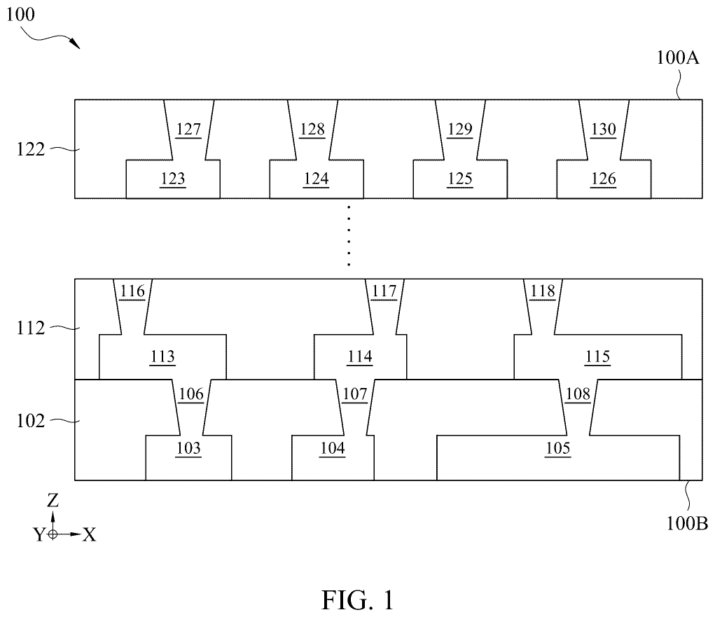

FIG. 1 illustrates a schematic diagram of an example redistribution structure 100, in accordance with various embodiments. For example, FIG. 1 illustrates a cross-sectional view (e.g., a cross-section cut along a plane expanded on the X direction and Z direction) of a portion of the example redistribution structure 100. It should be appreciated that the redistribution structure 100 of FIG. 1 is simplified for illustration purposes. Accordingly, the redistribution structure 100 can include any of various other components or features, while remaining within the scope of the present disclosure.

As shown, the redistribution structure 100 includes a number of redistribution layers 102, 112 . . . 122. Although three layers are shown, it should be understood that the redistribution structure 100 can include any number of redistribution layers, while remaining within the scope of the present disclosure. In various embodiments, the redistribution structure 100 can provide a conductive pattern that allows a pin-out contact pattern for a packaged semiconductor device (sometimes referred to as a package) different than a pattern of connectors on one or more semiconductor dies. Stated another way, the redistribution structure 100 can redistribute or otherwise rearrange a first pattern of a number of first connectors as a second pattern of a number of second connectors. Each of the redistribution layers 102 to 122 includes a number of conductive structures (e.g., conductive lines, vias) embedded in a dielectric material, where the conductive structures across the different redistribution layers 102 to 122 can collectively form such a conductive pattern.

For example in FIG. 1, the redistribution layer 102 includes conductive lines 103, 104, and 105, and vias 106, 107, and 108; the redistribution layer 112 includes conductive lines 113, 114, and 115, and vias 116, 117, and 118; and the redistribution layer 122 includes conductive lines 123, 124, 125, and 126, and vias 127, 128, 129, and 130. As will be discussed in further detail below, each of the conductive lines and vias, as disclosed herein, essentially consists of a metal material, and is embedded or otherwise surrounded by a dielectric material. Stated another way, each of the redistribution layers 102 to 122 embeds a number of conductive lines and a number of vias within a dielectric material.

The conductive line of one of the redistribution layers 102 to 122 can be (e.g., electrically) coupled to the conductive line of any of the other upper or lower redistribution layers 102 to 122 through at least one via, according to various embodiments. As a representative example, the via 106 electrically couples an overlying (or upper) conductive line 113 to an underlying (or lower) conductive line 103. In addition, the conductive lines may each extend along any direction(s), e.g., formed as a line having a lengthwise direction extending along a certain lateral direction, a pattern having plural portions each of which extends along a respective different lateral direction, or a plane extending along two lateral directions, according to a particular design. As such, these conductive lines and vias can collectively form a conductive pattern.

Further, such a conductive pattern, constituted by the conductive lines and vias, can convert a first connector pattern formed on a first side 100A of the redistribution structure 100 to a second connector pattern formed on a second side 100B of the redistribution structure 100. For example, a number of first connectors (not shown in FIG. 1) coupled to the vias 127 to 130, respectively, can form a first connector pattern. The first connector pattern can be configured to operatively (e.g., electrically) coupled to a number of semiconductor dies (which will be discussed in further detail below). The first connector pattern, through the conductive pattern constituted by at least some of the conductive lines and vias, can be converted to a second connector pattern formed by a number of second connectors (not shown in FIG. 1). These second connectors are coupled to the conductive lines 103 to 105, respectively. The second connector pattern can be configured to operatively (e.g., electrically) coupled to a substrate (which will be discussed in further detail below). Such first/second connectors can each include a solder ball, a metal pillar, a controlled collapse chip connection (C4) bump, a micro bump, an electroless nickel-electroless palladium-immersion gold technique (ENEPIG) formed bump, a through silicon/substrate via, a combination thereof (e.g., a metal pillar having a solder ball attached thereof), or the like. As a result, the redistribution structure 100 allows a number of semiconductor dies (each of which may have a certain function, e.g., a logic die, a memory die, etc.) to be integrated on a single substrate thereby forming a packaged semiconductor device.

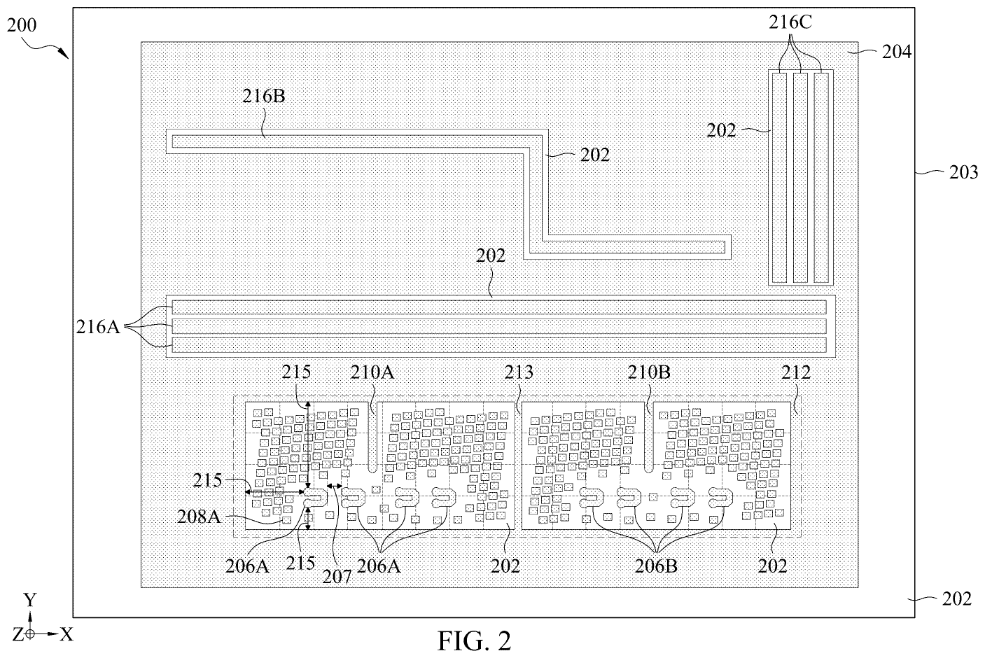

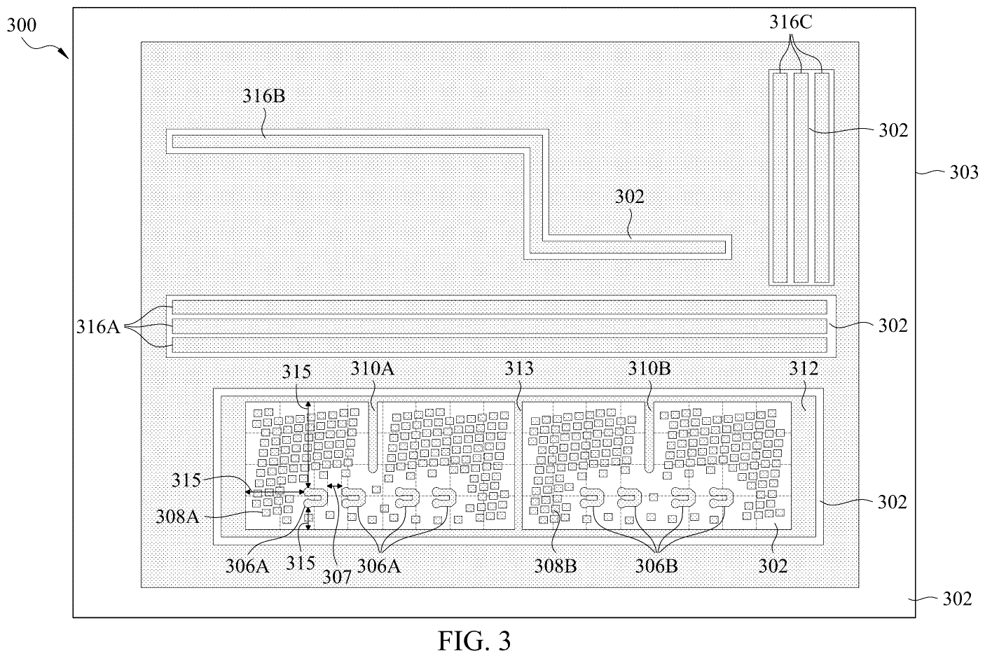

FIGS. 2 and 3 respectively illustrate example top views of one of the redistribution layers of the redistribution structure 100 of FIG. 1, in accordance with various embodiments. For example, redistribution layers 200 and 300 in FIGS. 2 and 3 may each represent the top view of a layout design of its corresponding conductive lines. It should be appreciated that the redistribution layers 200 and 300 of FIGS. 2 and 3 are simplified for illustration purposes. Accordingly, the redistribution layers 200 and 300 of FIGS. 2 and 3 can include any of various other components or features (e.g., patterns), while remaining within the scope of the present disclosure.

Referring first to FIG. 2, the redistribution layer 200 includes a dielectric material (or layer) 202 defined by a (e.g., chip or package) boundary 203. The redistribution layer 200 further includes a number of conductive structures, each of which is enclosed by a respective portion of the dielectric layer 202. For example, the redistribution layer 200 includes: a power/ground plane 204, a number of first high-speed (HS) signal routing paths 206A, a number of second HS signal routing paths 206B, a number of first dot-like conductive structures 208A, a number of second dot-like conductive structures 208B, a first power/ground reference structure 210A, a second power/ground reference structure 210B, a number of first non-high-speed (NHS) signal routing paths 216A, a second NHS signal routing path 216B, and a number of third NHS signal routing paths 216C. In some embodiments, each of the conductive structures shown in FIG. 2 may be an implementation of the conductive line of FIG. 1.

For example, the power/ground plane 204 may be formed as a plane expanded over the X direction and Y direction. In some embodiments, the power/ground plane 204 is configured to provide a supply voltage (e.g., VDD, VSS) to at least an electrically coupled semiconductor die. Alternatively stated, the power/ground plane 204 can carry a power supply voltage. Such a power/ground plane 204 can enclose or otherwise surround the first HS signal routing paths 206A and second HS signal routing paths 206B. The first HS signal routing paths 206A and second HS signal routing paths 206B are each configured to transmit, receive, or otherwise carry a signal operating in a relatively high frequency (e.g., from hundreds of megahertz to hundreds of gigahertz depending on the corresponding circuit design) for at least an electrically coupled semiconductor die. Although the HS signal routing paths 206A-B are each formed as a horseshoe-like structure in FIG. 2, it should be understood that the HS signal routing paths 206A-B can be formed as any of various other structures (e.g., a square, a rectangle, a line, etc.), while remaining within the scope of the present disclosure.

Further, the first HS signal routing paths 206A (which are typically configured to carry similar signals, e.g., operatively coupled to similar components of a semiconductor die) may be surrounded by the first dot-like conductive structures 208A; and the second HS signal routing paths 206B (which are typically configured to carry similar signals, e.g., operatively coupled to similar components of a semiconductor die) may be surrounded by the second dot-like conductive structures 208B. The first dot-like conductive structures 208A may be scattered around the first HS signal routing paths 206A (e.g., forming a polka dot pattern); and the second dot-like conductive structures 208B may be scattered around the second HS signal routing paths 206B (e.g., forming a polka dot pattern). Specifically in the example of FIG. 2, a first subset of the first dot-like conductive structures 208A surround two neighboring ones of the first HS signal routing paths 206A; a second subset of the first dot-like conductive structures 208A surround other two neighboring ones of the first HS signal routing paths 206A; a first subset of the second dot-like conductive structures 208B surround two neighboring ones of the second HS signal routing paths 206B; and a second subset of the second dot-like conductive structures 208B surround other two neighboring ones of the second HS signal routing paths 206B.

In various embodiments, the first dot-like conductive structures 208A and second dot-like conductive structures 208B are each electrically floating (i.e., electrically disconnected from any of supply voltages). With such floating dot-like conductive structures closely surrounding the corresponding HS signal routing path(s), various design rules, to which the HS signal routing path(s) are subjected, can be satisfied, even if dimensions of the HS signal routing path(s) continue to shrink. For example, a lateral spacing between the HS signal routing path and a closest one of the surrounding dot-like structures may be equal or close to the minimum distance specified by the design rules to which the HS signal routing path is subjected. As such, a lateral spacing between two neighboring HS signal routing paths can be optimally adjusted, while meeting the design rules. In a non-limiting example, a minimum spacing 207 between the two neighboring first HS signal routing paths 206A shown in FIG. 2 may be optimized or otherwise adjusted to be equal to or greater than about 20 micrometers (μm), based on the advanced technology node (e.g., single-digit nanometer or even sub-nanometer) of a semiconductor die to which the redistribution layer 200 is operatively coupled.

In various embodiments, the first power/ground reference structure 210A and second power/ground reference structure 210B are each tied to a power supply voltage, e.g., by merging with the power/ground plane 204, so as to provide a power/ground reference or a signal reference for the HS signal routing paths 206A/206B. The first power/ground reference structure 210A may be disposed around the HS signal routing paths 206A; and the second power/ground reference structure 210B may be disposed around the HS signal routing paths 206B. For example in FIG. 2, the first power/ground reference structure 210A extends along the Y direction, with a projection separating a first subset of the HS signal routing paths 206A and a second subset of the HS signal routing paths 206A; and the second power/ground reference structure 210B extends along the Y direction, with a projection separating a first subset of the HS signal routing paths 206B and a second subset of the HS signal routing paths 206B. In another example (not shown), the first power/ground reference structure 210A may extend along the Y direction, with a projection reaching one of the HS signal routing paths 206A; and the second power/ground reference structure 210B may extend along the Y direction, with a projection reaching one of the HS signal routing paths 206B.

Further, in the example of FIG. 2, the power/ground plane 204 may have a portion, e.g., 212, that serves as a guard ring (hereinafter “guard ring 212”) for the HS signal routing paths 206A and 206B. Stated another way, the guard ring 212 and the power/ground plane 204 are merged in the example redistribution layer 200 of FIG. 2. In such an embodiment, the guard ring 212 may be tied to the same electrical potential as the power/ground plane 204. In various embodiments, the guard ring 212 may be configured to avoid cross-talk between neighboring sets of signal routing paths, e.g., the cross-talk between any of the sets of HS signal routing path 216A or 216B and a neighboring set of signal routing paths. For example, the guard ring 212 can isolate the HS signal routing paths 206A and 206B from the NHS signal routing paths 216A, 216B, and 216C. Further, the guard ring 212 can include a portion 213 extending between (or separating) the two sets of HS signal routing paths 206A and 206B, which may respectively carry out-of-phase signals, in some embodiments. To accommodate the floating dot-like structures 208A and 208B, a minimum spacing 215 between the HS signal routing path 206A/206B and the guard ring 212 may be adjusted. As a non-limiting example, the spacing 215 may be equal to or greater than about 20μm, based on the advanced technology node (e.g., single-digit nanometer or even sub-nanometer) of a semiconductor die to which the redistribution layer 200 is operatively coupled.

The power/ground plane 204 can further enclose or otherwise surround the first NHS signal routing paths 216A, the second NHS signal routing path 216B, and the third NHS signal routing path 216C. The first NHS signal routing paths 216A, the second NHS signal routing path 216B, and the third NHS signal routing paths 216C are each configured to transmit, receive, or otherwise carry a signal operating in a relatively low frequency (e.g., from zero hertz to about one hundred hertz depending on the corresponding circuit design) for at least an electrically coupled semiconductor die. In general, the HS signal routing path is formed to have smaller dimensions than dimensions of the NHS signal routing path. For example in FIG. 2, the NHS signal routing paths 216A each extend along the X direction with a distance that is substantially greater than the distance with which the HS signal routing path 206A/B extends in any of the lateral directions. In another example, the NHS signal routing paths 216B has plural portions each extending along either the X direction or the Y direction with a distance that is substantially greater than the distance with which the HS signal routing path 206A/B extends in any of the lateral directions. In yet another example, the NHS signal routing paths 216C each extend along the Y direction with a distance that is substantially greater than the distance with which the HS signal routing path 206A/B extends in any of the lateral directions. It should be understood that the NHS signal routing paths 216A-C can each be formed as any of various other structure, while remaining within the scope of the present disclosure.

Referring next to FIG. 3, the redistribution layer 300 includes a dielectric material (or layer) 302 defined by a (e.g., chip or package) boundary 303. The redistribution layer 300 further includes a number of conductive structures, each of which is enclosed by a respective portion of the dielectric layer 302. For example, the redistribution layer 300 includes: a power/ground plane 304, a number of first high-speed (HS) signal routing paths 306A, a number of second HS signal routing paths 306B, a number of first dot-like conductive structures 308A, a number of second dot-like conductive structures 308B, a first power/ground reference structure 310A, a second power/ground reference structure 310B, a guard ring 312, a number of first non-high-speed (NHS) signal routing paths 316A, a second NHS signal routing path 316B, and a number of third NHS signal routing paths 316C. In some embodiments, each of the conductive structures shown in FIG. 3 may be an implementation of the conductive line of FIG. 1.

For example, the power/ground plane 304 may be formed as a plane expanded over the X direction and Y direction. In some embodiments, the power/ground plane 304 is configured to provide a supply voltage (e.g., VDD, VSS) to at least an electrically coupled semiconductor die. Alternatively stated, the power/ground plane 304 can carry a power supply voltage. Such a power/ground plane 304 can enclose or otherwise surround the first HS signal routing paths 306A and second HS signal routing paths 306B. The first HS signal routing paths 306A and second HS signal routing paths 306B are each configured to transmit, receive, or otherwise carry a signal operating in a relatively high frequency (e.g., from hundreds of megahertz to hundreds of gigahertz depending on the corresponding circuit design) for at least an electrically coupled semiconductor die. Although the HS signal routing paths 306A-B are each formed as a horseshoe-like structure in FIG. 3, it should be understood that the HS signal routing paths 306A-B can be formed as any of various other structures (e.g., a square, a rectangle, a line, etc.), while remaining within the scope of the present disclosure.

Further, the first HS signal routing paths 306A (which are typically configured to carry similar signals, e.g., operatively coupled to similar components of a semiconductor die) may be surrounded by the first dot-like conductive structures 308A; and the second HS signal routing paths 306B (which are typically configured to carry similar signals, e.g., operatively coupled to similar components of a semiconductor die) may be surrounded by the second dot-like conductive structures 308B. The first dot-like conductive structures 308A may be scattered around the first HS signal routing paths 306A (e.g., forming a polka dot pattern); and the second dot-like conductive structures 308B may be scattered around the second HS signal routing paths 306B (e.g., forming a polka dot pattern). Specifically in the example of FIG. 3, a first subset of the first dot-like conductive structures 308A surround two neighboring ones of the first HS signal routing paths 306A; a second subset of the first dot-like conductive structures 308A surround other two neighboring ones of the first HS signal routing paths 306A; a first subset of the second dot-like conductive structures 308B surround two neighboring ones of the second HS signal routing paths 306B; and a second subset of the second dot-like conductive structures 308B surround other two neighboring ones of the second HS signal routing paths 306B.

In various embodiments, the first dot-like conductive structures 308A and second dot-like conductive structures 308B are each electrically floating (i.e., electrically disconnected from any of supply voltages). With such floating dot-like conductive structures closely surrounding the corresponding HS signal routing path(s), various design rules, to which the HS signal routing path(s) are subjected, can be satisfied, even if dimensions of the HS signal routing path(s) continue to shrink. For example, a lateral spacing between the HS signal routing path and a closest one of the surrounding dot-like structures may be equal or close to the minimum distance specified by the design rules to which the HS signal routing path is subjected. As such, a lateral spacing between two neighboring HS signal routing paths can be optimally adjusted, while meeting the design rules. In a non-limiting example, a minimum spacing 307 between the two neighboring first HS signal routing paths 306A shown in FIG. 3 may be optimized or otherwise adjusted to be equal to or greater than about 20 micrometers (μm), based on the advanced technology node (e.g., single-digit nanometer or even sub-nanometer) of a semiconductor die to which the redistribution layer 300 is operatively coupled.

In various embodiments, the first power/ground reference structure 310A and second power/ground reference structure 310B are each tied to a power supply voltage, e.g., by coupling to the power/ground plane 304, so as to provide a power/ground reference or a signal reference for the HS signal routing paths 306A/306B. The first power/ground reference structure 310A may be disposed around the HS signal routing paths 306A; and the second power/ground reference structure 310B may be disposed around the HS signal routing paths 306B. For example in FIG. 3, the first power/ground reference structure 310A extends along the Y direction, with a projection separating a first subset of the HS signal routing paths 306A and a second subset of the HS signal routing paths 306A; and the second power/ground reference structure 310B extends along the Y direction, with a projection separating a first subset of the HS signal routing paths 306B and a second subset of the HS signal routing paths 306B.

In the example of FIG. 3, the HS signal routing paths 306A and 306B may be further surrounded by the guard ring 312, which is surrounded by the power/ground plane 304. The guard ring 312 and the power/ground plane 304 are isolated from each other in the example redistribution layer 300 of FIG. 3. In such an embodiment, the guard ring 312 may be tied to an electrical potential the same as or different than the electrical potential of the power/ground plane 304. In various embodiments, the guard ring 312 may be configured to avoid cross-talk between neighboring sets of signal routing paths, e.g., the cross-talk between any of the sets of HS signal routing path 316A or 316B and a neighboring set of signal routing paths. For example, the guard ring 312 can isolate the HS signal routing paths 306A and 306B from the NHS signal routing paths 316A, 316B, and 316C. Further, the guard ring 312 can include a portion 313 extending between (or separating) the two sets of HS signal routing paths 306A and 306B, which may respectively carry out-of-phase signals, in some embodiments. To accommodate the floating dot-like structures 308A and 308B, a minimum spacing 315 between the HS signal routing path 306A/306B and the guard ring 312 may be adjusted. As a non-limiting example, the spacing 315 may be equal to or greater than about 20 μm, based on the advanced technology node (e.g., single-digit nanometer or even sub-nanometer) of a semiconductor die to which the redistribution layer 300 is operatively coupled.

The power/ground plane 304 can further enclose or otherwise surround the first NHS signal routing paths 316A, the second NHS signal routing path 316B, and the third NHS signal routing path 316C. The first NHS signal routing paths 316A, the second NHS signal routing path 316B, and the third NHS signal routing paths 316C are each configured to transmit, receive, or otherwise carry a signal operating in a relatively low frequency (e.g., from zero hertz to about one hundred hertz depending on the corresponding circuit design) for at least an electrically coupled semiconductor die. In general, the HS signal routing path is formed to have smaller dimensions than dimensions of the NHS signal routing path. For example in FIG. 3, the NHS signal routing paths 316A each extend along the X direction with a distance that is substantially greater than the distance with which the HS signal routing path 306A/B extends in any of the lateral directions. In another example, the NHS signal routing paths 316B has plural portions each extending along either the X direction or the Y direction with a distance that is substantially greater than the distance with which the HS signal routing path 306A/B extends in any of the lateral directions. In yet another example, the NHS signal routing paths 316C each extend along the Y direction with a distance that is substantially greater than the distance with which the HS signal routing path 306A/B extends in any of the lateral directions. It should be understood that the NHS signal routing paths 316A-C can each be formed as any of various other structure, while remaining within the scope of the present disclosure.

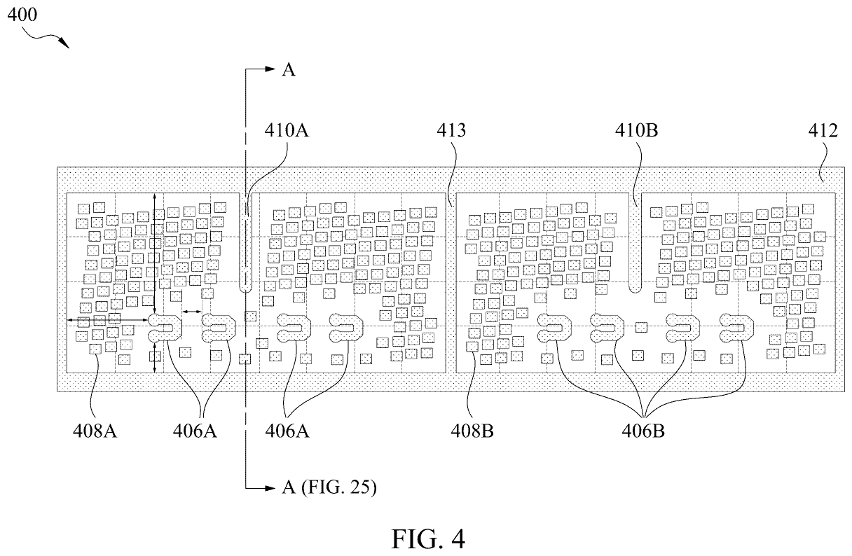

FIGS. 4, 5, 6, 7, 8, 9, 10, 11, 12, and 13 respectively illustrate other example top views of one of the redistribution layers of the redistribution structure 100 of FIG. 1, in accordance with various embodiments. Similarly, redistribution layers 400, 500, 600, 700, 800, 900, 1000, 1100, 1200, and 1300 in FIGS. 4 to 13 may each represent the top view of a layout design of its corresponding conductive lines.

It should be appreciated that the redistribution layers 400 to 1300 are simplified for illustration purposes. Accordingly, the redistribution layers 400 to 1300 can include any of various other components or features (e.g., patterns), while remaining within the scope of the present disclosure. For example, the power/ground plane and NHS signal routing paths (and the dielectric layer embedding these conductive structures) are not shown in any of the example redistribution layers 400 to 1300. Further, each of the redistribution layers 400 to 1300 has a similar pattern of the HS signal routing paths and the dot-like structures (except for the redistribution layer 1200 of FIG. 12) to the redistribution layers 200 and 300, and thus, the following discussions will be focused on their respective guard rings and/or power/ground reference structures.

In FIG. 4, the redistribution layer 400 includes HS signal routing paths 406A-B and dot-like structures 408A-B similar to the HS signal routing paths and dot-like structures shown in FIGS. 2 and 3. Also similarly, the redistribution layer 400 includes power/ground reference structures 410A-B similar to the power/ground reference structures shown in FIGS. 2 and 3. The redistribution layer 400 includes a guard ring 412 surrounding these structures. Specifically, the guard ring 412 fully encloses the HS signal routing paths 406A-B, dot-like structures 408A-B, and power/ground reference structures 410A-B. The guard ring 412 may sometimes be referred to as having a close-end shape. Further, the guard ring 412 includes a portion 413 separating the HS signal routing paths 406A and the HS signal routing paths 406B (similar to the extending portion shown in FIGS. 2 and 3). The guard ring 412 is connected to the power/ground reference structures 410A-B. The guard ring 412 can be merged with (e.g., similar to the guard ring 212) or isolated from (e.g., similar to the guard ring 312) a power/ground plane.

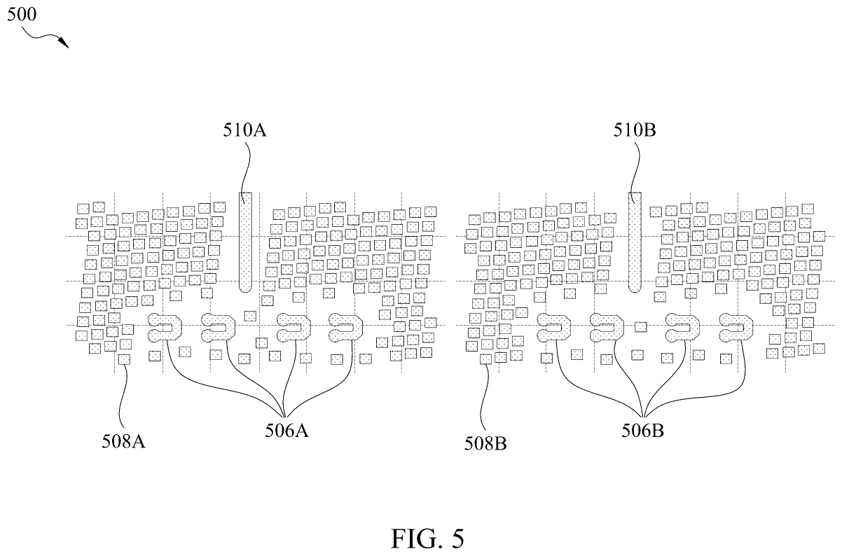

In FIG. 5, the redistribution layer 500 includes HS signal routing paths 506A-B and dot-like structures 508A-B similar to the HS signal routing paths and dot-like structures shown in FIGS. 2 and 3. Also similarly, the redistribution layer 500 includes power/ground reference structures 510A-B similar to the power/ground reference structures shown in FIGS. 2 and 3. The redistribution layer 500 includes no guard ring surrounding these structures. As such, each of the HS signal routing paths 506A-B and dot-like structures 508A-B may be isolated from a corresponding power/ground plane.

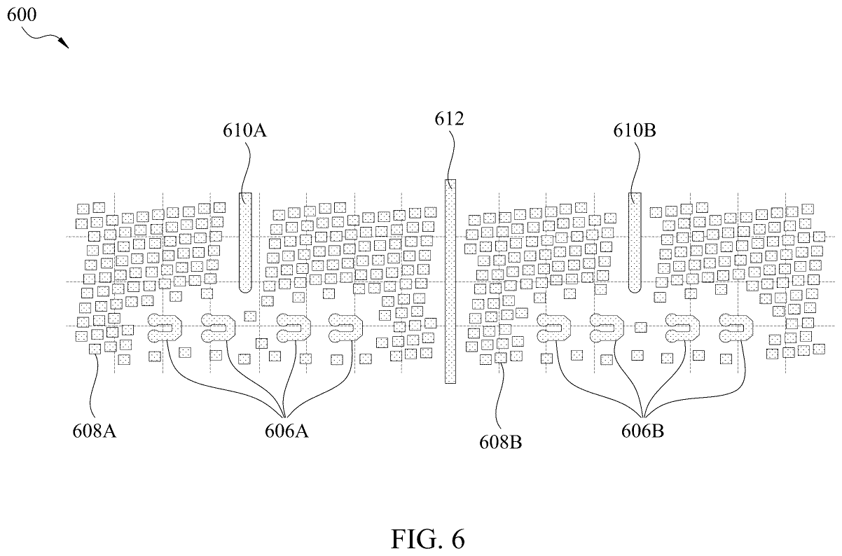

In FIG. 6, the redistribution layer 600 includes HS signal routing paths 606A-B and dot-like structures 608A-B similar to the HS signal routing paths and dot-like structures shown in FIGS. 2 and 3. Also similarly, the redistribution layer 600 includes power/ground reference structures 610A-B similar to the power/ground reference structures shown in FIGS. 2 and 3. The redistribution layer 600 includes a guard ring 612 separating the HS signal routing paths 606A, dot-like structures 608A, and power/ground reference structure 610A from the HS signal routing paths 606B, dot-like structures 608B, and power/ground reference structure 610B. The guard ring 612 may sometimes be referred to as having an open-end shape, e.g., an “I” shape. The guard ring 612 can be merged with (e.g., similar to the guard ring 212) or isolated from (e.g., similar to the guard ring 312) a power/ground plane.

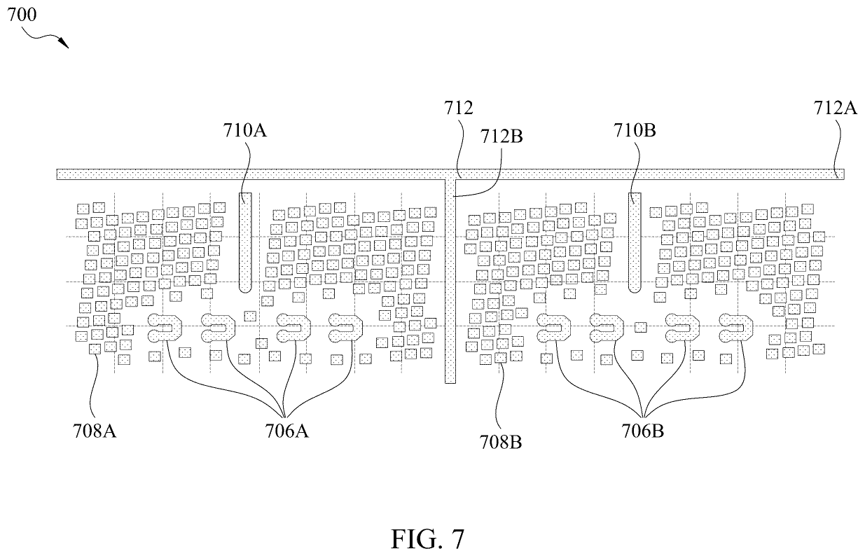

In FIG. 7, the redistribution layer 700 includes HS signal routing paths 706A-B and dot-like structures 708A-B similar to the HS signal routing paths and dot-like structures shown in FIGS. 2 and 3. Also similarly, the redistribution layer 700 includes power/ground reference structures 710A-B similar to the power/ground reference structures shown in FIGS. 2 and 3. The redistribution layer 700 includes a guard ring 712 having: a first portion 712A extending across the HS signal routing paths 706A-B, dot-like structures 708A-B, and power/ground reference structures 710A-B; and a second portion 712B separating the HS signal routing paths 706A, dot-like structures 708A, and power/ground reference structure 710A from the HS signal routing paths 706B, dot-like structures 708B, and power/ground reference structure 710B. The guard ring 712 may sometimes be referred to as having an open-end shape. For example, the guard ring 712 has a shape with two “L” shapes merged at one of each L shape's legs (e.g., the portion 712B). The guard ring 712 can be connected to or isolated from (as shown in FIG. 7) the power/ground reference structures 710A-B. The guard ring 712 can be merged with (e.g., similar to the guard ring 212) or isolated from (e.g., similar to the guard ring 312) a power/ground plane.

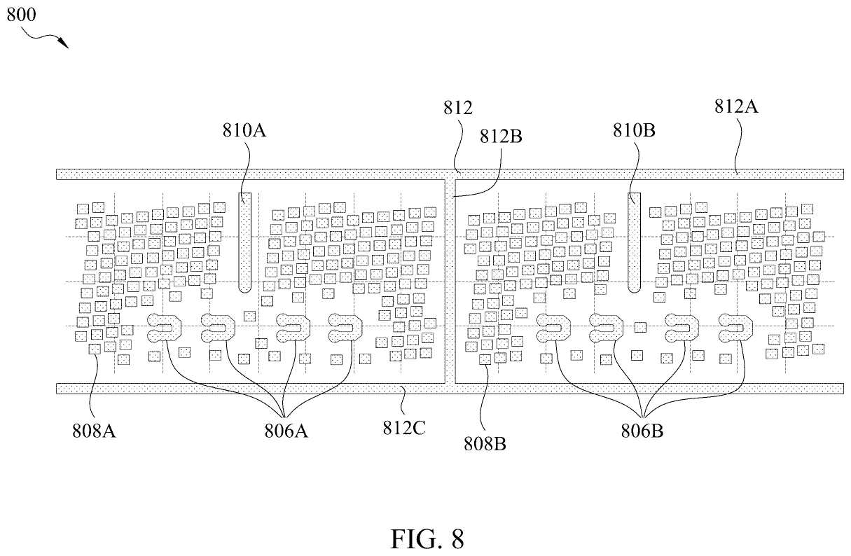

In FIG. 8, the redistribution layer 800 includes HS signal routing paths 806A-B and dot-like structures 808A-B similar to the HS signal routing paths and dot-like structures shown in FIGS. 2 and 3. Also similarly, the redistribution layer 800 includes power/ground reference structures 810A-B similar to the power/ground reference structures shown in FIGS. 2 and 3. The redistribution layer 800 includes a guard ring 812 having: a first portion 812A extending across the HS signal routing paths 806A-B, dot-like structures 808A-B, and power/ground reference structures 810A-B; a second portion 812B separating the HS signal routing paths 806A, dot-like structures 808A, and power/ground reference structure 810A from the HS signal routing paths 806B, dot-like structures 808B, and power/ground reference structure 810B; and a third portion 812C extending across the HS signal routing paths 806A-B, dot-like structures 808A-B, and power/ground reference structures 810A-B. The portions 812A and 812C are parallel with each other, with the portion 812B connecting the portions 812A and 812C at their respective mid points. Accordingly, the guard ring 812 may sometimes be referred to as having an open-end shape. For example, the guard ring 812 has a shape with two “U” shapes rotated with 90 degrees clockwise and counterclockwise, respectively, and merged at each U shape's bottom boundary (e.g., the portion 812B). The guard ring 812 can be connected to or isolated from (as shown in FIG. 8) the power/ground reference structures 810A-B. The guard ring 812 can be merged with (e.g., similar to the guard ring 212) or isolated from (e.g., similar to the guard ring 312) a power/ground plane.

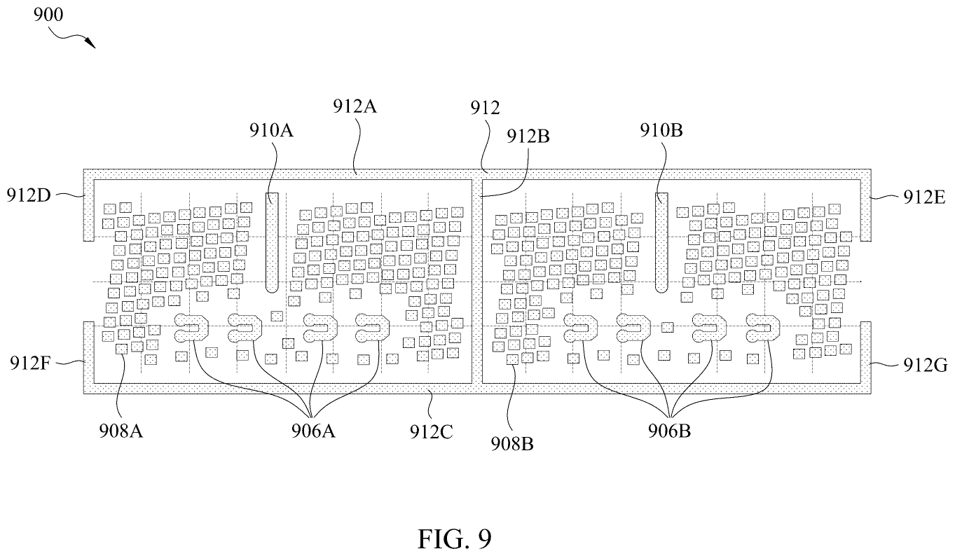

In FIG. 9, the redistribution layer 900 includes HS signal routing paths 906A-B and dot-like structures 908A-B similar to the HS signal routing paths and dot-like structures shown in FIGS. 2 and 3. Also similarly, the redistribution layer 900 includes power/ground reference structures 910A-B similar to the power/ground reference structures shown in FIGS. 2 and 3. The redistribution layer 900 includes a guard ring 912 having: a first portion 912A extending across the HS signal routing paths 906A-B, dot-like structures 908A-B, and power/ground reference structures 910A-B; a second portion 912B separating the HS signal routing paths 906A, dot-like structures 908A, and power/ground reference structure 910A from the HS signal routing paths 906B, dot-like structures 908B, and power/ground reference structure 910B; a third portion 912C extending across the HS signal routing paths 906A-B, dot-like structures 908A-B, and power/ground reference structures 910A-B; fourth and fifth portions 912D and 912E connected to both ends of the first portion 912A, respectively; and sixth and seventh portions 912F and 912G connected to both ends of the third portion 912C, respectively. The portions 912A and 912C are parallel with each other, with the portion 912B connecting the portions 912A and 912C at their respective mid points. Accordingly, the guard ring 912 may sometimes be referred to as having an open-end shape. For example, the guard ring 912 has a shape with two “C” shapes mirrored from each other and merged at each C shape's side boundary (e.g., the portion 912B). The guard ring 912 can be connected to or isolated from (as shown in FIG. 9) the power/ground reference structures 910A-B. The guard ring 912 can be merged with (e.g., similar to the guard ring 212) or isolated from (e.g., similar to the guard ring 312) a power/ground plane.

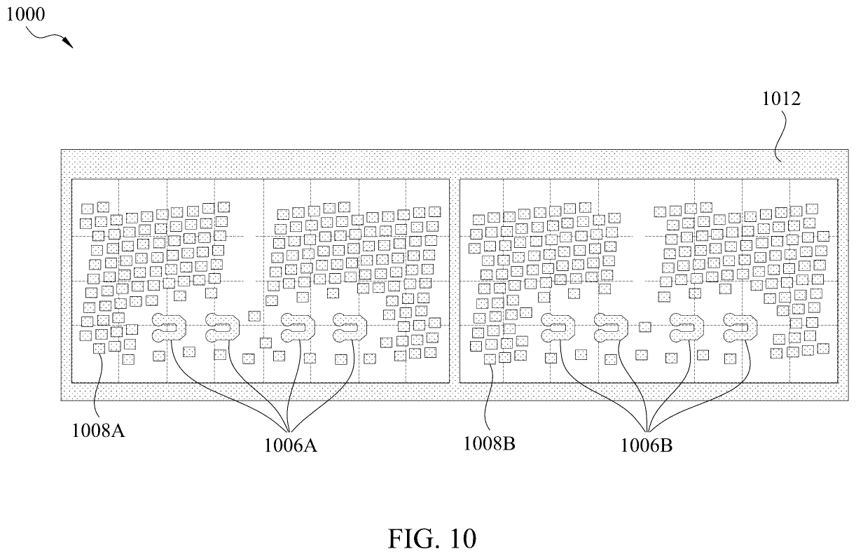

In FIG. 10, the redistribution layer 1000 includes HS signal routing paths 1006A-B and dot-like structures 1008A-B similar to the HS signal routing paths and dot-like structures shown in FIGS. 2 and 3. The redistribution layer 1000, however, does not include any power/ground reference structure. The redistribution layer 1000 includes a guard ring 1012 surrounding these structures. Specifically, the guard ring 1012 fully encloses the HS signal routing paths 1006A-B and dot-like structures 1008A-B. The guard ring 1012 may sometimes be referred to as having a close-end shape. Further, the guard ring 1012 includes a portion 1013 separating the HS signal routing paths 1006A and the HS signal routing paths 1006B (similar to the extending portion shown in FIGS. 2 and 3). The guard ring 1012 can be merged with (e.g., similar to the guard ring 212) or isolated from (e.g., similar to the guard ring 312) a power/ground plane.

In FIG. 11, the redistribution layer 1100 includes HS signal routing paths 1106A-B and dot-like structures 1108A-B similar to the HS signal routing paths and dot-like structures shown in FIGS. 2 and 3. Also similarly, the redistribution layer 1100 includes power/ground reference structures 1110A-B similar to the power/ground reference structures shown in FIGS. 2 and 3. The redistribution layer 1100 includes a guard ring 1112 surrounding these structures. Specifically, the guard ring 1112 fully encloses the HS signal routing paths 1106A-B, dot-like structures 1108A-B, and power/ground reference structures 1110A-B. The guard ring 1112 may sometimes be referred to as having a close-end shape. Further, the guard ring 1112 includes a portion 1113 separating the HS signal routing paths 1106A and the HS signal routing paths 1106B (similar to the extending portion shown in FIGS. 2 and 3). The guard ring 1112 is isolated from the power/ground reference structures 1110A-B. The guard ring 1112 can be merged with (e.g., similar to the guard ring 212) or isolated from (e.g., similar to the guard ring 312) a power/ground plane.

In FIG. 12, the redistribution layer 1200 includes HS signal routing paths 1206A-B similar to the HS signal routing paths shown in FIGS. 2 and 3. Also similarly, the redistribution layer 1200 includes power/ground reference structures 1210A-B similar to the power/ground reference structures shown in FIGS. 2 and 3. However, the redistribution layer 1200 may not include any dot-like structures shown in FIGS. 2 and 3, according to some other embodiments. The redistribution layer 1200 includes a guard ring 1212 surrounding these structures. Specifically, the guard ring 1212 fully encloses the HS signal routing paths 1206A-B and power/ground reference structures 1210A-B. The guard ring 1212 may sometimes be referred to as having a close-end shape. Further, the guard ring 1212 includes a portion 1213 separating the HS signal routing paths 1206A and the HS signal routing paths 1206B (similar to the extending portion shown in FIGS. 2 and 3). The guard ring 1212 is connected to the power/ground reference structures 1210A-B. The guard ring 1212 can be merged with (e.g., similar to the guard ring 212) or isolated from (e.g., similar to the guard ring 312) a power/ground plane.

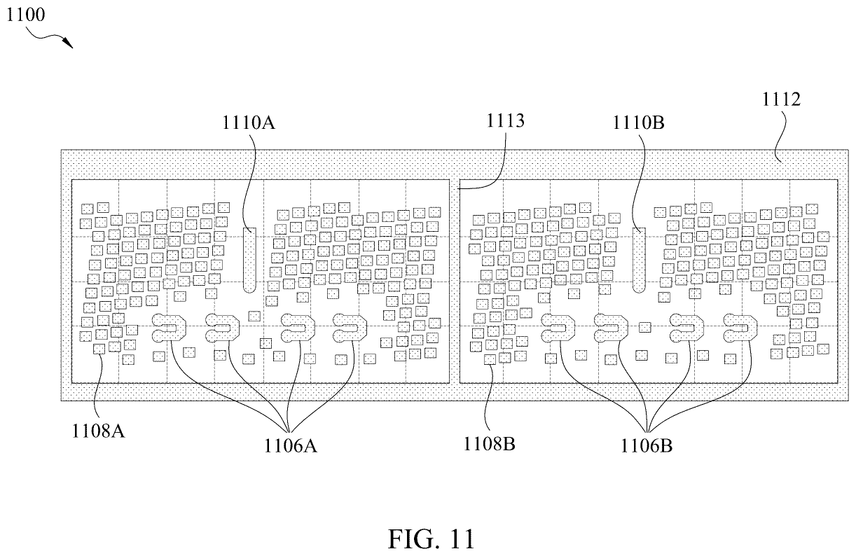

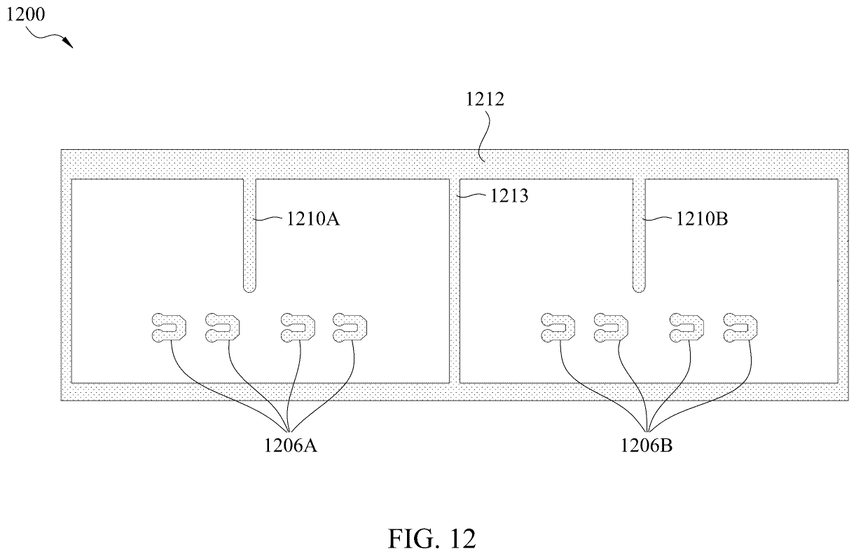

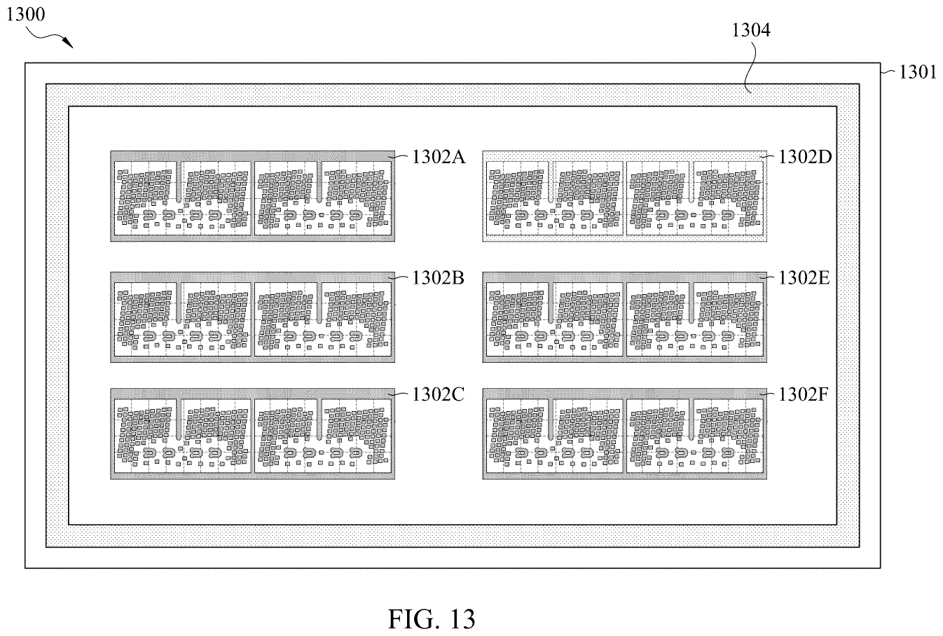

In FIG. 13, the redistribution layer 1300 includes a number of “local” guard rings 1302A, 1302B, 1302C, 1302D, 1302E, and 1302F, each of which is substantially similar to the guard ring 412 (FIG. 4) that fully surrounds a number of HS signal routing paths and has an extending portion further separating a first subset of the HS signal routing paths from a second subset of the HS signal routing paths. In some embodiments, within a chip or package boundary 1301, the redistribution layer 1300 can include a “global” guard ring 1304 lining along the boundary 1301. The global guard ring 1304 can enclose a power/ground plane connected to or isolated from the local guard rings 1302A-F.

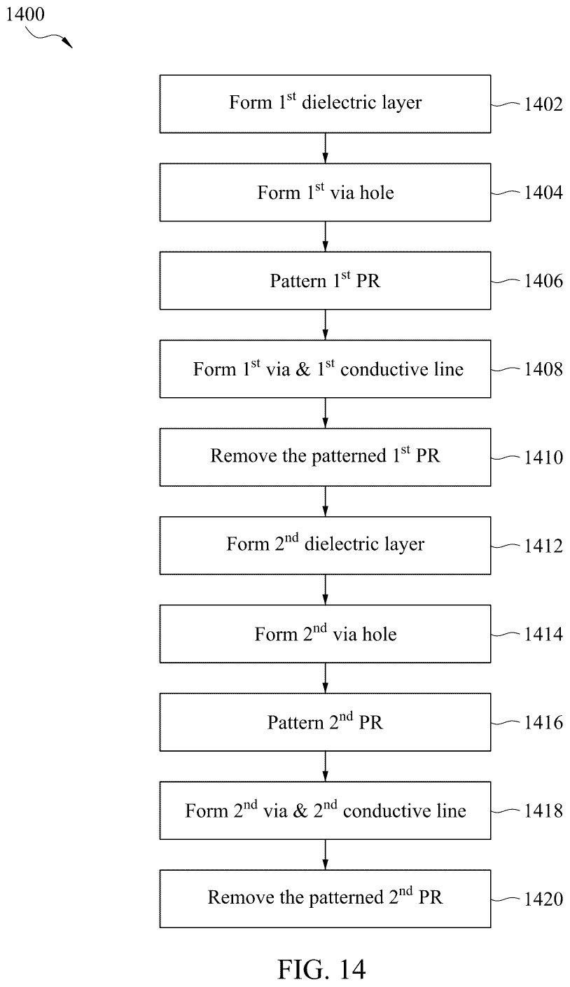

FIG. 14 illustrates a flowchart of an example method 1400 to form at least a portion of a redistribution structure, as disclosed herein, in accordance with various embodiments. For example, at least some of the operations (or steps) of the method 1400 can be performed to fabricate, make, or otherwise form a redistribution structure having a number of redistribution layers, each of which includes a number of HS signal routing paths each surrounded by a number of floating dot-like structures. Additionally, the example layouts, as discussed with respect to FIGS. 2-13, can be used in one or more of the operations of the method 1400 to form the disclosed redistribution structure.

It should be noted that the method 1400 is merely an example, and is not intended to limit the present disclosure. Accordingly, it should be understood that additional operations may be provided before, during, and after the method 1400 of FIG. 14, and that some other operations may only be briefly described herein. In some embodiments, the operations of the method 1400 may be associated with cross-sectional views of a portion of an example redistribution structure 1500 that includes one or more of the redistribution layers discussed with respect to FIGS. 2-13, at various fabrication stages as shown in FIGS. 15, 16, 17, 18, 19, 20, 21, 22, 23, and 24, respectively, which will be discussed in further detail below.

In brief overview, the method 1400 starts with operation 1402 of forming a first dielectric layer. The method 1400 proceeds to operation 1404 of forming a first via hole. The method 1400 proceeds to operation 1406 of patterning a first photoresist layer. The method 1400 proceeds to operation 1408 of forming a first via and a first conductive line. The method 1400 proceeds to operation 1410 of removing the patterned first photoresist layer. The method 1400 proceeds to operation 1412 of forming a second dielectric layer. The method 1400 proceeds to operation 1414 of forming a second via hole. The method 1400 proceeds to operation 1416 of patterning a second photoresist layer. The method 1400 proceeds to operation 1418 of forming a second via and a second conductive line. The method 1400 proceeds to operation 1420 of removing the patterned second photoresist layer.

Corresponding to operation 1402 of FIG. 14, FIG. 15 illustrates a cross-sectional view of the redistribution structure 1500 including a first dielectric layer 1504 formed over a substrate (or carrier) 1502 at one of the various stages of fabrication, in accordance with various embodiments.

In some embodiments, the substrate 1502 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. The substrate 1502 may be an interposer. Additionally, the substrate 1502 may be a SOI substrate. Generally, an SOI substrate includes a layer of a semiconductor material such as epitaxial silicon, germanium, silicon germanium, SOI, silicon germanium on insulator (SGOI), or combinations thereof. f. Devices, such as transistors, capacitors, resistors, diodes, and the like, may be formed in and/or on a surface of the substrate 1502. Further, connectors, such as through silicon/substrate vias, and the like, may be formed in and/or on a surface of the substrate 1502 that faces the first dielectric layer 1504. The substrate 1502 is, in one alternative embodiment, based on an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate 1502.

In some other embodiments, the carrier 1502 can provide temporary mechanical and structural support for various features during subsequent processing steps. In this manner, damage to the semiconductor dies, which will be bonded to the redistribution structure 1500, can be reduced or prevented. The carrier 1502 may comprise, for example, glass, ceramic, and the like. In some embodiments, the carrier 1502 may be substantially free of any active devices and/or functional circuitry. In some embodiments, a release layer (not shown) may be optionally formed between the first dielectric layer 1504 and the carrier 1502. The release layer is used to attach the first dielectric layer 1504 to the carrier 1502. Such a release layer may be any suitable adhesive, such as an ultraviolet (UV) glue, or the like.

The first dielectric layer 1504 is formed of a polymer, which may be a photo-sensitive material such as polybenzoxazole (PBO), polyimide, benzocyclobutene (BCB), or the like, that may be patterned using lithography. In other embodiments, the first dielectric layer 1504 is formed of a nitride such as silicon nitride, an oxide such as silicon oxide, PhosphoSilicate Glass (PSG), BoroSilicate Glass (BSG), Boron-doped PhosphoSilicate Glass (BPSG), or the like. The first dielectric layer 1504 may be formed by spin coating, lamination, CVD, the like, or a combination thereof.

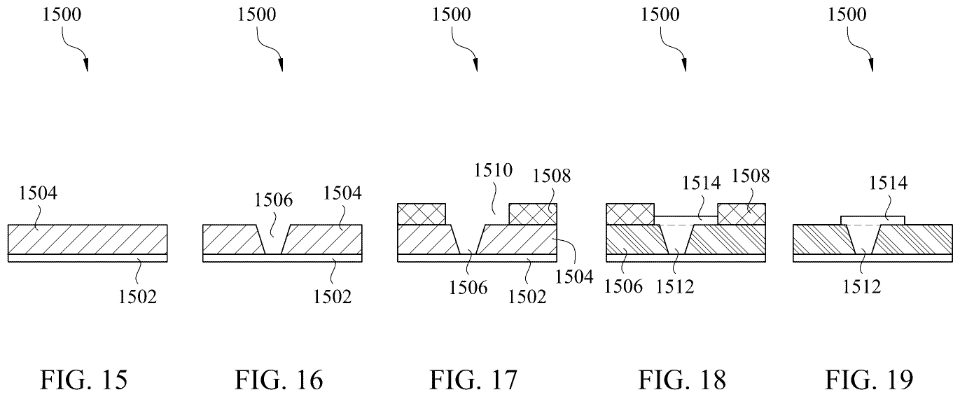

Corresponding to operation 1404 of FIG. 14, FIG. 16 illustrates a cross-sectional view of the redistribution structure 1500 in which the first dielectric layer 1504 is patterned to form a first via hole 1506 at one of the various stages of fabrication, in accordance with various embodiments. The first via hole 1506 may be formed by etching the (e.g., blanket) first dielectric layer 1504 through a mask layer formed over the blanket first dielectric layer 1504, until a portion of the substrate/carrier 1502 is exposed. In the embodiment where one or more connectors are formed along the contacting surface of the substrate 1502, the etching process may stop until the via hole 1506 exposes a corresponding one of the connectors. The etching process can include a wet etching process, a dry etching process, or combinations thereof.

Corresponding to operation 1406 of FIG. 14, FIG. 17 illustrates a cross-sectional view of the redistribution structure 1500 in which a first photoresist layer 1508 is patterned at one of the various stages of fabrication, in accordance with various embodiments. The first photoresist layer (or otherwise photo-sensible layers) 1508 is first formed over the first dielectric layer 1504 as a blanket layer. Next, one or more etching processes are performed to pattern the blanket first photoresist layer 1508, thereby forming a line hole 1510. In some embodiments, such a patterning process may be performed according to one or more patterns of the above-discussed layouts.

Corresponding to operation 1408 of FIG. 14, FIG. 18 illustrates a cross-sectional view of the redistribution structure 1500 including a first via 1512 and a first conductive line 1514 at one of the various stages of fabrication, in accordance with various embodiments. The first via 1512 and first conductive line 1514 may be formed by filling the via hole 1506 and at least a portion of the line hole 1510, respectively, with a conductive material. The conductive material may comprise a metal, like copper, titanium, tungsten, aluminum, or the like. The conductive material may be formed by plating, such as electroplating or electroless plating, or the like.

Corresponding to operation 1410 of FIG. 14, FIG. 19 illustrates a cross-sectional view of the redistribution structure 1500 in which the patterned first photoresist layer 1508 is removed at one of the various stages of fabrication, in accordance with various embodiments. After forming the first via 1512 and first conductive line 1514, the patterned first photoresist layer 1508 is removed. The first photoresist layer 1508 may be removed by an acceptable ashing or stripping process, such as using an oxygen plasma or the like.

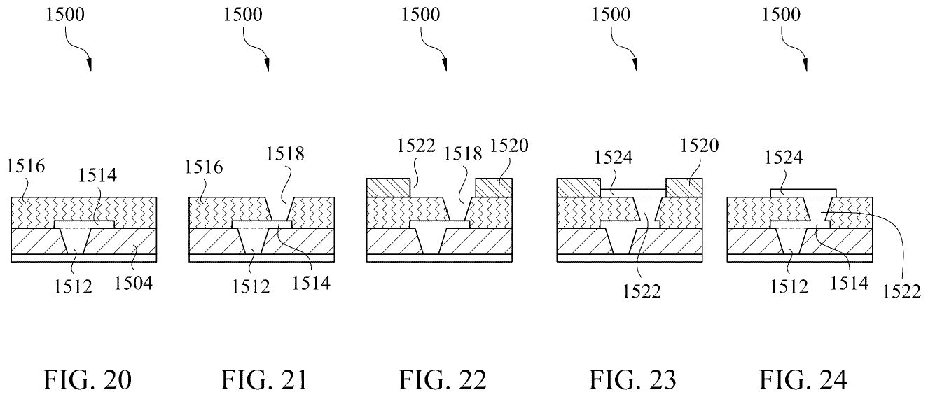

Corresponding to operation 1412 of FIG. 14, FIG. 20 illustrates a cross-sectional view of the redistribution structure 1500 including a second dielectric layer 1516 formed over the first dielectric layer 1504 at one of the various stages of fabrication, in accordance with various embodiments. The second dielectric layer 1516 is formed of a polymer, which may be a photo- sensitive material such as polybenzoxazole (PBO), polyimide, benzocyclobutene (BCB), or the like, that may be patterned using lithography. In other embodiments, the second dielectric layer 1516 is formed of a nitride such as silicon nitride, an oxide such as silicon oxide, PhosphoSilicate Glass (PSG), BoroSilicate Glass (BSG), Boron-doped PhosphoSilicate Glass (BPSG), or the like. The second dielectric layer 1516 may be formed by spin coating, lamination, CVD, the like, or a combination thereof.

Corresponding to operation 1414 of FIG. 14, FIG. 21 illustrates a cross-sectional view of the redistribution structure 1500 in which the second dielectric layer 1516 is patterned to form a second via hole 1518 at one of the various stages of fabrication, in accordance with various embodiments. The second via hole 1518 may be formed by etching the (e.g., blanket) second dielectric layer 1516 through a mask layer formed over the blanket second dielectric layer 1516, until a portion of the first conductive line 1514 is exposed. The etching process can include a wet etching process, a dry etching process, or combinations thereof.

Corresponding to operation 1416 of FIG. 14, FIG. 22 illustrates a cross-sectional view of the redistribution structure 1500 in which a second photoresist layer 1520 is patterned at one of the various stages of fabrication, in accordance with various embodiments. The second photoresist layer (or otherwise photo-sensible layers) 1520 is first formed over the second dielectric layer 1516 as a blanket layer. Next, one or more etching processes are performed to pattern the blanket second photoresist layer 1520, thereby forming a line hole 1522. In some embodiments, such a patterning process may be performed according to one or more patterns of the above-discussed layouts.

Corresponding to operation 1418 of FIG. 14, FIG. 23 illustrates a cross-sectional view of the redistribution structure 1500 including a second via 1522 and a second conductive line 1524 at one of the various stages of fabrication, in accordance with various embodiments. The second via 1522 and second conductive line 1524 may be formed by filling the via hole 1518 and at least a portion of the line hole 1522, respectively, with a conductive material. The conductive material may comprise a metal, like copper, titanium, tungsten, aluminum, or the like. The conductive material may be formed by plating, such as electroplating or electroless plating, or the like.

Corresponding to operation 1420 of FIG. 14, FIG. 24 illustrates a cross-sectional view of the redistribution structure 1500 in which the patterned second photoresist layer 1520 is removed at one of the various stages of fabrication, in accordance with various embodiments. After forming the second via 1522 and second conductive line 1524, the patterned second photoresist layer 1520 is removed. The second photoresist layer 1520 may be removed by an acceptable ashing or stripping process, such as using an oxygen plasma or the like.

In accordance with various embodiments, the first conductive line 1514 and second via 1522 may be referred to as a first (or bottommost) redistribution layer of the disclosed redistribution structure 1500. By repeating at least some of the operations of the method 1400 (e.g., the operations 1412 to 1420), the redistribution structure 1500 can include one or more upper redistribution layers stacked or otherwise disposed over the first redistribution layer. In some embodiments, the first via 1512 may serve as a connector configured to couple the redistribution structure 1500 to a package substrate, while a conductive line in a topmost redistribution layer of the redistribution structure 1500 may be connected to a connector configured to couple the redistribution structure 1500 to a semiconductor die. For example, upon the redistribution structure 1500, which includes a desired number of redistribution layers, being formed, a packaged semiconductor device can be formed by performing at least some of the following operations: attaching (or bonding) a number of semiconductor dies to the redistribution structure 1500 through a number of first connectors disposed along one side of the redistribution structure 1500; and attaching (or bonding) a package substrate to the redistribution structure 1500 through a number of second connectors disposed along the other side of the redistribution structure 1500.

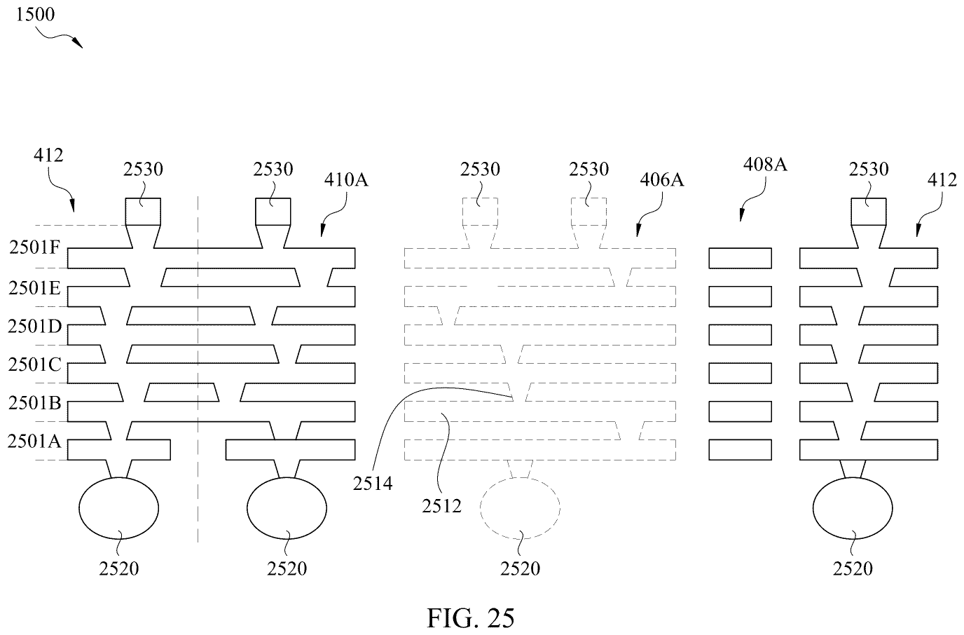

FIG. 25 illustrates a cross-sectional view of a portion of such a redistribution structure 1500, which includes a number of the disclosed redistribution layers, in accordance with various embodiments. As a representative example, various conductive structures of each redistribution layer of the redistribution structure 1500 are made according to the layout 400 of FIG. 4. Moreover, the cross-sectional view of FIG. 25 is cut along a symbolic line A-A, as shown in FIG. 4, which extends from one edge of the guard ring 412, runs along the power/ground reference structure 410A and across one or more of the dot-like structures 408A, and extends to the other opposite edge of the guard ring 412.

It should be noted that this cross-section does not run into any of the HS signal routing paths 406A (FIG. 4). The cross-sectional view of FIG. 25, however, still shows one of the HS signal routing paths 406A for illustration purposes, and thus, such a HS signal routing path 406A is shown in dotted lines. As illustrated, the redistribution structure 1500 includes the guard ring 412, power/ground reference structure 410A, HS signal routing paths 406A, and dot-like structure 408A formed over six redistribution layers, 2501A, 2501B, 2501C, 2501D, 2501E, and 2501F. The redistribution structure 1500 can include more or less redistribution layers, while remaining within the scope of the present disclosure.

Each of the redistribution layers includes at least one conductive line (e.g., 2512) and one via (e.g., 2514), except for the dot-like structure 408A. The conductive line 2512 and via 2514 are substantially similar to the conductive line 1514/1524 and via 1512/1522 discussed above with respect to FIGS. 15-24, respectively. In some embodiments, the dot-like structure 408A (and any other dot-like structures as disclosed herein) may include a number of isolated or otherwise discrete conductive lines only, i.e., no via formed between neighboring conductive lines, as shown in FIG. 25. However, it should be appreciated that the dot-like structure 408A (and any other dot-like structures as disclosed herein) can include a via connected between neighboring conductive lines, while remaining within the scope of the present disclosure.

As further shown in FIG. 25, a number of first connectors (e.g., C4 bumps) 2520 are coupled to a first side of the redistribution structure 1500, and a number of second connectors (e.g., micro bumps) 2530 are coupled to a second (opposite) side of the redistribution structure 1500. Such connectors 2520 and 2530 allow the redistribution structure 1500 to electrically couple a number of semiconductor dies (e.g., logic dies, memory dies, etc.) to a package substrate, thereby forming a packaged semiconductor device, which will be discussed as follows.

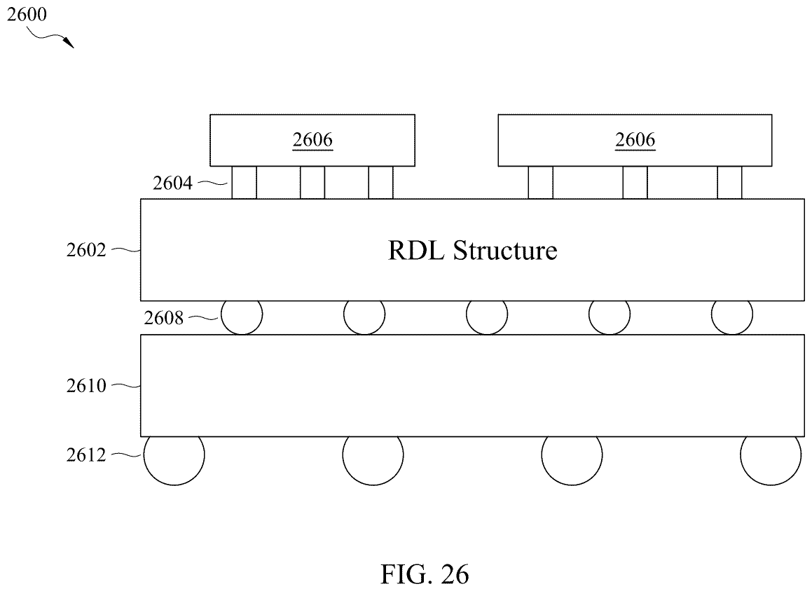

FIGS. 26, 27, 28, and 29 respectively illustrate a number of example packaged semiconductor devices (or packages) 2600, 2700, 2800, and 2900, each of which implements the disclosed redistribution structure (e.g., includes at least one redistribution structure having a number of the redistribution layers discussed above with respect to FIGS. 2-13), in accordance with various embodiments. It should be noted that the packages 2600 to 2900 are simplified for illustration purposes, and thus, each of the packages 2600 to 2900 can include any of various other features/components, while remaining within the scope of the present disclosure.

In FIG. 26, the package 2600 includes a redistribution structure 2602 having a number of the redistribution layers discussed above with respect to FIGS. 2-13. The package 2600 includes a number of first connectors 2604 disposed on a first side of the redistribution structure 2602, and a number of second connectors 2608 disposed on a second, opposite side of the redistribution structure 2602. The first connectors 2604 are configured to couple the redistribution structure 2602 to a number of semiconductor dies 2606, and the second connectors 2608 are configured to couple the redistribution structure 2602 to a package substrate 2610. Further, on a side of the package substrate 2610 opposite to the side facing the redistribution structure 2602, the package 2600 includes a number of third connectors 2612. Such a package 2600 may sometimes be referred to as a Chip-on-Wafer-on-Substrate-Redistribution (CoWoS-R) integrated circuit.

In some embodiments, the first/second/third connectors 2604/2608/2612 may be solder balls, metal pillars, controlled collapse chip connection (C4) bumps, micro bumps, electroless nickel-electroless palladium-immersion gold technique (ENEPIG) formed bumps, combination thereof (e.g., a metal pillar having a solder ball attached thereof), or the like. The connectors 2604/2608/2612 may include a conductive material such as solder, copper, aluminum, gold, nickel, silver, palladium, tin, the like, or a combination thereof. In some embodiments, connectors 2604/2608/2612 comprise a eutectic material and may comprise a solder bump or a solder ball, as examples. The solder material may be, for example, lead-based and lead-free solders, such as Pb-Sn compositions for lead-based solder; lead-free solders including InSb; tin, silver, and copper (SAC) compositions; and other eutectic materials that have a common melting point and form conductive solder connections in electrical applications. For lead-free solder, SAC solders of varying compositions may be used, such as SAC 105 (Sn 98.5%, Ag 1.0%, Cu 0.5%), SAC 305, and SAC 405, as examples. Lead-free connectors such as solder balls may be formed from SnCu compounds as well, without the use of silver (Ag). Alternatively, lead-free solder connectors may include tin and silver, Sn-Ag, without the use of copper. The connectors 2604/2608/2612 may form a grid, such as a ball grid array (BGA). In some embodiments, a reflow process may be performed, giving the connectors 2604/2608/2612 a shape of a partial sphere in some embodiments. Alternatively, the connectors 2604/2608/2612 may comprise other shapes.

The connectors 2604/2608/2612 may also comprise non-spherical conductive connectors, for example. In some embodiments, the connectors 2604/2608/2612 comprise metal pillars (such as a copper pillar) formed by a sputtering, printing, electro plating, electroless plating, CVD, or the like, with or without a solder material thereon. The metal pillars may be solder free and have substantially vertical sidewalls or tapered sidewalls.

The connectors 2604/2608/2612 may also include an under bump metallization (UBM) formed and patterned over an uppermost metallization pattern in accordance with some embodiments, thereby forming an electrical connection with an uppermost metallization layer. The UBMs provides an electrical connection upon which an electrical connector, e.g., a solder ball/bump, a conductive pillar, or the like, may be placed. In an embodiment, the UBMs include a diffusion barrier layer, a seed layer, or a combination thereof. The diffusion barrier layer may include Ti, TiN, Ta, TaN, or combinations thereof. The seed layer may include copper or copper alloys. However, other metals, such as nickel, palladium, silver, gold, aluminum, combinations thereof, and multi-layers thereof, may also be included. In an embodiment, UBMs are formed using sputtering. In other embodiments, electro plating may be used.

The semiconductor dies 2606 may each include a main body, an interconnect region, and connectors. The main body may comprise any number of dies, substrates, transistors, active devices, passive devices, or the like. The interconnect region may provide a conductive pattern that allows a pin-out contact pattern for the main body. The connectors may be disposed on a side of each die, and may be used to physically and electrically connect the die to connectors 2604. The connectors may be electrically connected to the main body through the interconnect region. In various embodiments, the semiconductor dies 2606 may each be implemented as a logic die, a memory die, or a combination thereof. Example logic dies include Central Processing Units (CPUs), Application processors (APs), system on chips (SOCs), Application Specific Integrated Circuits (ASICs), or other types of logic dies including logic transistors therein. Example memory dies include Dynamic Random Access Memory (DRAM) dies, Static Random Access Memory (SRAM) dies, High-Bandwidth Memory (HBM) dies, Micro-Electro-Mechanical System (MEMS) dies, Hybrid Memory Cube (HMC) dies, or the like.

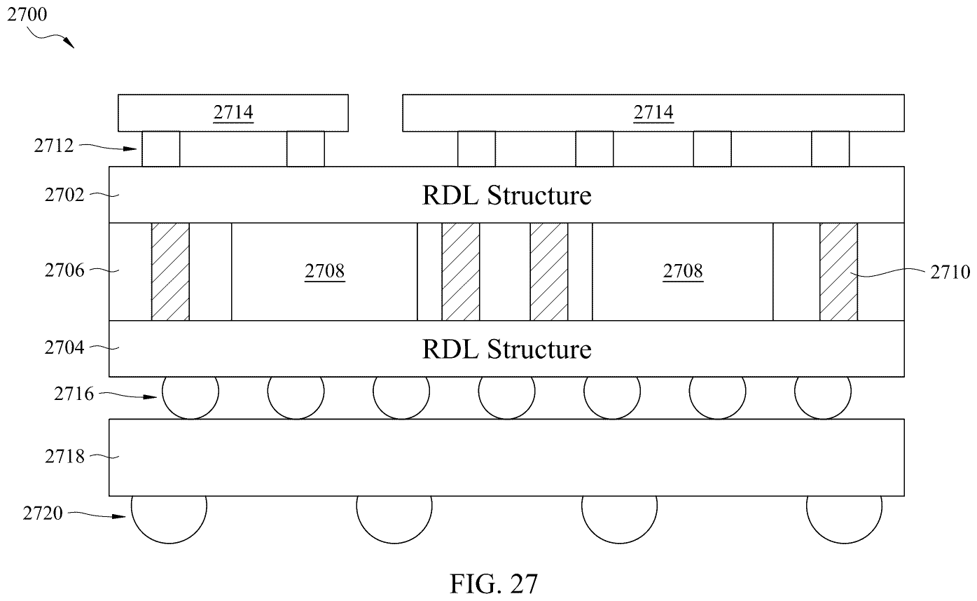

In FIG. 27, the package 2700 includes a first redistribution structure 2702 and a second redistribution structure 2704, each of which has a number of the redistribution layers discussed above with respect to FIGS. 2-13. The package 2700 includes a molding material 2706 with the redistribution structures 2702 and 2704 disposed on its both sides, respectively. The molding material 2706 may include a molding compound, a molding underfill, an epoxy, or a resin. Within the molding material 2706, the package 2700 includes a number of interposers (sometimes referred to as Local Silicon Interconnection (LSI)) 2708 and a number of through vias 2710. The interposer 2708 can provide an increased number of electrical paths, connections, and the like, in a smaller area than would otherwise be possible. The package 2700 includes a number of first connectors 2712 disposed on a side of the first redistribution structure 2702 opposite to the side facing the molding material 2706, and a number of second connectors 2716 disposed on a side of the second redistribution structure 2704 opposite to the side facing the molding material 2706. The first connectors 2712 are configured to couple the first redistribution structure 2702 to a number of semiconductor dies 2714, and the second connectors 2716 are configured to couple the second redistribution structure 2704 to a package substrate 2718. Further, on a side of the package substrate 2718 opposite to the side facing the redistribution structure 2704, the package 2700 includes a number of third connectors 2720. The connectors 2712/2716/2720 may be implemented similarly to the connectors 2604/2608/2612 (FIG. 26), and thus, the discussions are not repeated. Also, the semiconductor dies 2714 may be implemented similarly to the semiconductor dies 2606 (FIG. 26), and thus, the discussion are not repeated. Such a package 2700 may sometimes be referred to as a Chip-on-Wafer-on-Substrate-LSI (CoWoS-L) integrated circuit.

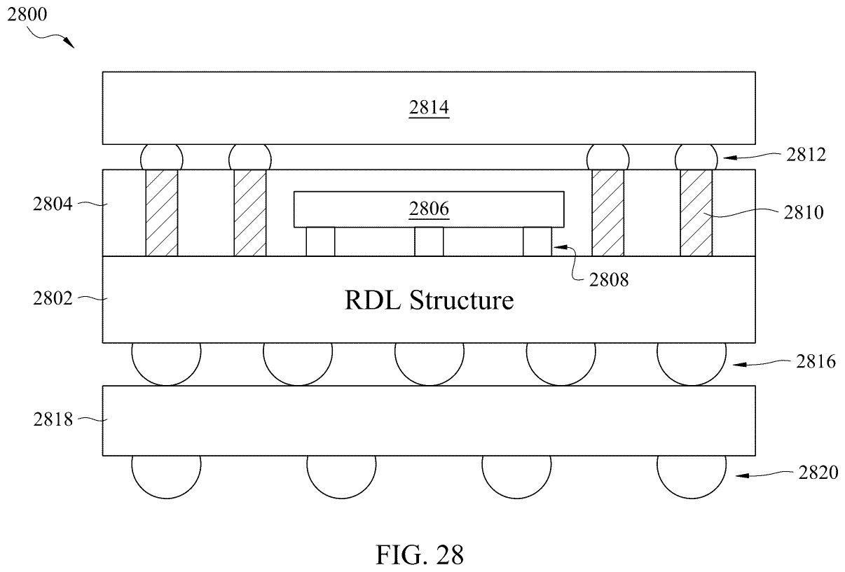

In FIG. 28, the package 2800 includes a redistribution structure 2802 having a number of the redistribution layers discussed above with respect to FIGS. 2-13. The package 2800 includes a molding material 2804 disposed on a side of the redistribution structure 2802. The molding material 2804 may include a molding compound, a molding underfill, an epoxy, or a resin. Within the molding material 2804, the package 2800 includes a first semiconductor die 2806 coupled to the redistribution structure 2802 through a number of first connectors 2808. The package 2800 includes a number of through vias 2810 in the molding material 2804. The package 2800 includes a second semiconductor die 2814 coupled to the redistribution structure 2802 through a number of second connectors 2812, which are coupled to the through vias 2810. On a side of the redistribution structure 2802 opposite to the side facing the molding material 2804, the package 2800 includes a number of third connectors 2816 configured to couple the redistribution structure 2802 to a package substrate 2818. Further, on a side of the package substrate 2818 opposite to the side facing the redistribution structure 2802, the package 2800 includes a number of fourth connectors 2820. The connectors 2808/2812/2816/2820 may be implemented similarly to the connectors 2604/2608/2612 (FIG. 26), and thus, the discussions are not repeated. In some embodiments, the connectors 2808/2812/2816/2820 may not contain any C4 bumps. Also, the semiconductor dies 2806 and 2814 may be implemented as the logic die and the memory die, respectively, discussed above with respect to FIG. 26, and thus, the discussion are not repeated. Such a package 2800 may sometimes be referred to as an Integrated Fan-Out_Package-on-Package (InFo_PoP) integrated circuit.

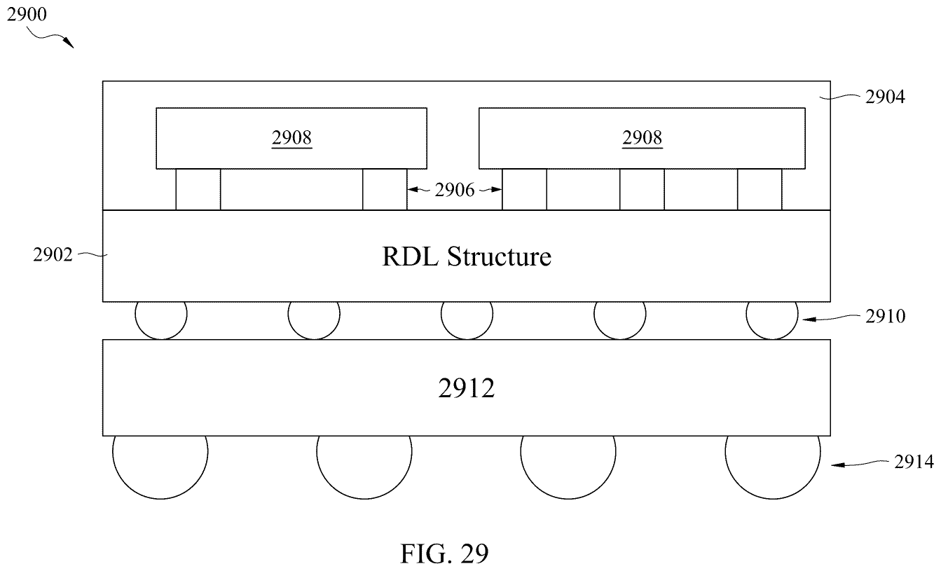

In FIG. 29, the package 2900 includes a redistribution structure 2902 having a number of the redistribution layers discussed above with respect to FIGS. 2-13. The package 2900 includes a molding material 2904 disposed on a first side of the redistribution structure 2902. The molding material 2904 may include a molding compound, a molding underfill, an epoxy, or a resin. Within the molding material 2904, the package 2900 includes a number of first connectors 2904, which are configured to couple the redistribution structure 2902 to a number of semiconductor dies 2908 laterally spaced from one another. The package 2900 includes a number of second connectors 2910 disposed on a second, opposite side of the redistribution structure 2902. The second connectors 2910 are configured to couple the redistribution structure 2902 to a package substrate 2912. Further, on a side of the package substrate 2912 opposite to the side facing the redistribution structure 2902, the package 2900 includes a number of third connectors 2914. The connectors 2906/2910/2914 may be implemented similarly to the connectors 2604/2608/2612 (FIG. 26), and thus, the discussions are not repeated. Also, the semiconductor dies 2908 may be implemented similarly to the semiconductor dies 2606 (FIG. 26), and thus, the discussion are not repeated. Such a package 2900 may sometimes be referred to as an Integrated Fan-Out_on-Substrate (InFo_oS) integrated circuit.

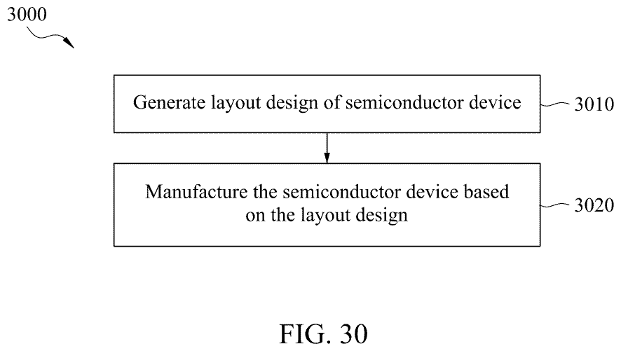

FIG. 30 is a flowchart of a method 3000 of forming or manufacturing a semiconductor device, in accordance with some embodiments. It is understood that additional operations may be performed before, during, and/or after the method 3000 depicted in FIG. 30. In some embodiments, the method 3000 is usable to form a semiconductor device, according to various layout designs as disclosed herein.

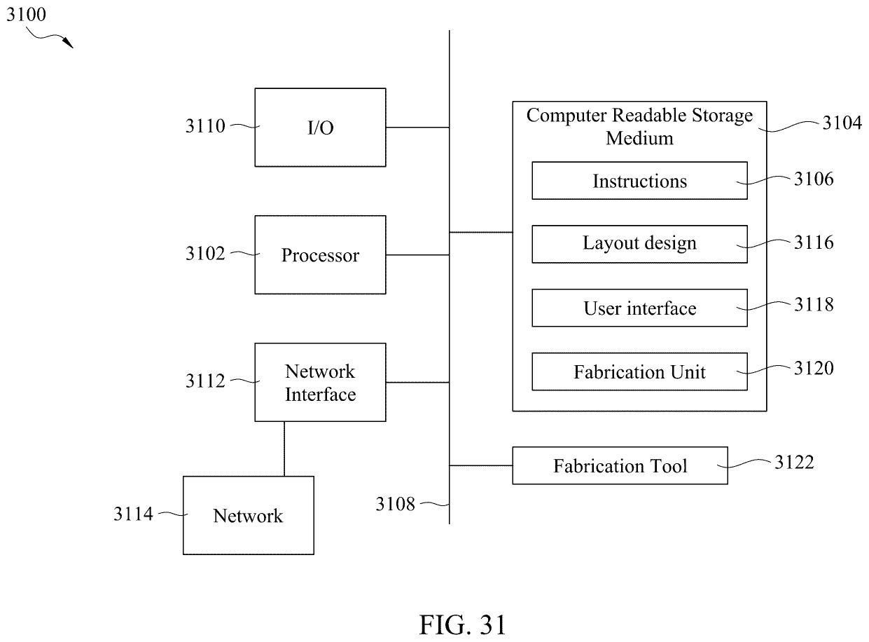

In operation 3010 of the method 3000, a layout design of a semiconductor device (e.g., the layouts discussed with respect to FIGS. 2-13) is generated. The operation 3010 is performed by a processing device (e.g., processor 3102 of FIG. 31) configured to execute instructions for generating a layout design. In one approach, the layout design is generated by placing layout designs of one or more standard cells through a user interface. In one approach, the layout design is automatically generated by a processor executing a synthesis tool that converts a logic design (e.g., Verilog) into a corresponding layout design. In some embodiments, the layout design is rendered in a graphic database system (GDSII) file format.

In operation 3020 of the method 3000, a semiconductor device (e.g., at least a portion of each of the packages 2600 to 2900) is manufactured based on the layout design. In some embodiments, the operation 3020 of the method 3000 includes manufacturing at least one mask based on the layout design, and manufacturing the a semiconductor device based on the at least one mask. A number of example manufacturing operations of the operation 3020 may be included in the method 1400 of FIG. 14 discussed above.

FIG. 31 is a schematic view of a system 3100 for designing and manufacturing an IC layout design, in accordance with some embodiments. The system 3100 generates or places one or more IC layout designs, as described herein. In some embodiments, the system 3100 manufactures one or more semiconductor devices based on the one or more IC layout designs, as described herein. The system 3100 includes a hardware processor 3102 and a non-transitory, computer readable storage medium 3104 encoded with, e.g., storing, the computer program code 3106, e.g., a set of executable instructions. The computer readable storage medium 3104 is configured for interfacing with manufacturing machines for producing the semiconductor device. The processor 3102 is electrically coupled to the computer readable storage medium 3104 by a bus 3108. The processor 3102 is also electrically coupled to an I/O interface 3110 by the bus 3108. A network interface 3112 is also electrically connected to the processor 3102 by the bus 3108. Network interface 3112 is connected to a network 3114, so that the processor 3102 and the computer readable storage medium 3104 are capable of connecting to external elements via network 3114. The processor 3102 is configured to execute the computer program code 3106 encoded in the computer readable storage medium 3104 in order to cause the system 3100 to be usable for performing a portion or all of the operations as described in method 3000.

In some embodiments, the processor 3102 is a central processing unit (CPU), a multi-processor, a distributed processing system, an application specific integrated circuit (ASIC), and/or a suitable processing unit.

In some embodiments, the computer readable storage medium 3104 is an electronic, magnetic, optical, electromagnetic, infrared, and/or a semiconductor system (or apparatus or device). For example, the computer readable storage medium 3104 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 3104 includes a compact disk-read only memory (CD-ROM), a compact disk-read/write (CD-R/W), and/or a digital video disc (DVD).

In some embodiments, the storage medium 3104 stores the computer program code 3106 configured to cause the system 3100 to perform the method 1400. In some embodiments, the storage medium 3104 also stores information needed for performing method 3000 as well as information generated during performance of method 3000, such as layout design 3116, user interface 3118, fabrication unit 3120, and/or a set of executable instructions to perform the operation of method 3000.

In some embodiments, the storage medium 3104 stores instructions (e.g., the computer program code 3106) for interfacing with manufacturing machines. The instructions (e.g., the computer program code 3106) enable the processor 3102 to generate manufacturing instructions readable by the manufacturing machines to effectively implement the method 3000 during a manufacturing process.

The system 3100 includes the I/O interface 3110. The I/O interface 3110 is coupled to external circuitry. In some embodiments, the I/O interface 3110 includes a keyboard, keypad, mouse, trackball, trackpad, and/or cursor direction keys for communicating information and commands to the processor 3102.

The system 3100 also includes the network interface 3112 coupled to the processor 3102. The network interface 3112 allows the system 3100 to communicate with the network 3114, to which one or more other computer systems are connected. The network interface 3112 includes wireless network interfaces such as BLUETOOTH, WIFI, WIMAX, GPRS, or WCDMA; or wired network interface such as ETHERNET, USB, or IEEE-13154. In some embodiments, the method 3000 is implemented in two or more systems 3100, and information such as layout design, user interface and fabrication unit are exchanged between different systems 3100 by the network 3114.

The system 3100 is configured to receive information related to a layout design through the I/O interface 3110 or network interface 3112. The information is transferred to the processor 3102 by the bus 3108 to determine a layout design for producing an IC. The layout design is then stored in the computer readable medium 3104 as the layout design 3116. The system 3100 is configured to receive information related to a user interface through the I/O interface 3110 or network interface 3112. The information is stored in the computer readable medium 3104 as the user interface 3118. The system 3100 is configured to receive information related to a fabrication unit through the I/O interface 3110 or network interface 3112. The information is stored in the computer readable medium 3104 as the fabrication unit 3120. In some embodiments, the fabrication unit 3120 includes fabrication information utilized by the system 3100.

In some embodiments, the method 3000 is implemented as a standalone software application for execution by a processor. In some embodiments, the method 3000 is implemented as a software application that is a part of an additional software application. In some embodiments, the method 3000 is implemented as a plug-in to a software application. In some embodiments, the method 3000 is implemented as a software application that is a portion of an EDA tool. In some embodiments, the method 3000 is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, the method 3000 is implemented by a manufacturing device to manufacture an integrated circuit using a set of masks manufactured based on one or more layout designs generated by the system 3100. In some embodiments, the system 3100 includes a manufacturing device (e.g., fabrication tool 3122) to manufacture an integrated circuit using a set of masks manufactured based on one or more layout designs of the present disclosure. In some embodiments, the system 3100 of FIG. 31 generates layout designs of an IC that are smaller than other approaches. In some embodiments, the system 3100 of FIG. 31 generates layout designs of a semiconductor device that occupy less area than other approaches.

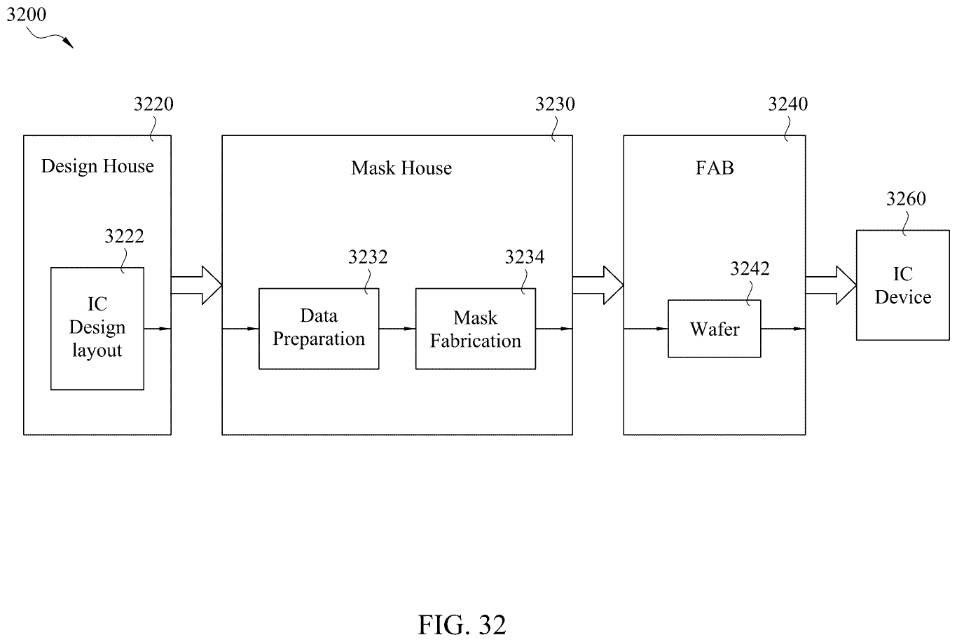

FIG. 32 is a block diagram of an integrated circuit (IC)/semiconductor device manufacturing system 3200, and an IC manufacturing flow associated therewith, in accordance with at least one embodiment of the present disclosure.

In FIG. 32, the IC manufacturing system 3200 includes entities, such as a design house 3220, a mask house 3230, and an IC manufacturer/fabricator (“fab”) 3240, that interact with one another in the design, development, and manufacturing cycles and/or services related to manufacturing an IC device (semiconductor device) 3260. The entities in system 3200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 3220, mask house 3230, and IC fab 3240 is owned by a single company. In some embodiments, two or more of design house 3220, mask house 3230, and IC fab 3240 coexist in a common facility and use common resources.

The design house (or design team) 3220 generates an IC design layout 3222. The IC design layout 3222 includes various geometrical patterns designed for the IC device 3260. The geometrical patterns correspond to patterns of metal, oxide, or semiconductor layers that make up the various components of the IC device 3260 to be fabricated. The various layers combine to form various IC features. For example, a portion of the IC design layout 3222 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 3220 implements a proper design procedure to form the IC design layout 3222. The design procedure includes one or more of logic design, physical design or place and route. The IC design layout 3222 is presented in one or more data files having information of the geometrical patterns. For example, the IC design layout 3222 can be expressed in a GDSII file format or DFII file format.

The mask house 3230 includes mask data preparation 3232 and mask fabrication 3234. The mask house 3230 uses the IC design layout 3222 to manufacture one or more masks to be used for fabricating the various layers of the IC device 3260 according to the IC design layout 3222. The mask house 3230 performs the mask data preparation 3232, where the IC design layout 3222 is translated into a representative data file (“RDF”). The mask data preparation 3232 provides the RDF to the mask fabrication 3234. The mask fabrication 3234 includes a mask writer. A mask writer converts the RDF to an image on a substrate, such as a mask (reticle) or a semiconductor wafer. The design layout is manipulated by the mask data preparation 3232 to comply with particular characteristics of the mask writer and/or requirements of the IC fab 3240. In FIG. 32, the mask data preparation 3232 and mask fabrication 3234 are illustrated as separate elements. In some embodiments, the mask data preparation 3232 and mask fabrication 3234 can be collectively referred to as mask data preparation.

In some embodiments, the mask data preparation 3232 includes optical proximity correction (OPC) which uses lithography enhancement techniques to compensate for image errors, such as those that can arise from diffraction, interference, other process effects and the like. OPC adjusts the IC design layout 3222. In some embodiments, the mask data preparation 3232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 3232 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 3234, which may undo part of the modifications performed by OPC in order to meet mask creation rules.

In some embodiments, the mask data preparation 3232 includes lithography process checking (LPC) that simulates processing that will be implemented by the IC fab 3240 to fabricate the IC device 3260. LPC simulates this processing based on the IC design layout 3222 to create a simulated manufactured device, such as the IC device 3260. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 3222.

It should be understood that the above description of the mask data preparation 3232 has been simplified for the purposes of clarity. In some embodiments, the mask data preparation 3232 includes additional features such as a logic operation (LOP) to modify the IC design layout according to manufacturing rules. Additionally, the processes applied to the IC design layout 3222 during the mask data preparation 3232 may be executed in a variety of different orders.

After the mask data preparation 3232 and during mask fabrication 3234, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the photosensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 3234 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 3240 is an IC fabrication entity that includes one or more manufacturing facilities for the fabrication of a variety of different IC products. In some embodiments, the IC fab 3240 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 3240 uses the mask (or masks) fabricated by the mask house 3230 to fabricate the IC device 3260. Thus, the IC fab 3240 at least indirectly uses the IC design layout 3222 to fabricate the IC device 3260. In some embodiments, a semiconductor wafer 1642 is fabricated by the IC fab 3240 using the mask (or masks) to form the IC device 3260. The semiconductor wafer 3242 includes a silicon substrate or other proper substrate having material layers formed thereon. Semiconductor wafer further includes one or more of various doped regions, dielectric features, multilevel interconnects, and the like (formed at subsequent manufacturing steps).

The system 3200 is shown as having the design house 3220, mask house 3230, and IC fab 3240 as separate components or entities. However, it should be understood that one or more of the design house 3220, mask house 3230 or IC fab 3240 are part of the same component or entity.

In one aspect of the present disclosure, a semiconductor device is disclosed. The semiconductor device includes a first semiconductor die. The semiconductor device includes a redistribution structure disposed over a first side of the first semiconductor die and comprising a plurality of layers. At least a first one of the plurality of layers comprises a first power/ground plane embedded in a dielectric material and configured to provide a first supply voltage for the first semiconductor die. The first power/ground plane encloses a plurality of first conductive structures that are each operatively coupled to the first semiconductor die, and a plurality of second conductive structures scattered around the plurality of first conductive structures.

In another aspect of the present disclosure, a semiconductor device is disclosed. The semiconductor device includes a redistribution layer configured to redistribute connectors of a semiconductor die. The redistribution layer comprises a plurality of conductive structures embedded in a dielectric material. A first subset of the plurality of conductive structures are each configured to carry a first type of signal generated by the semiconductor die. A second subset of the plurality of conductive structures are configured to collectively surround the first subset of conductive structures, the second subset of conductive structures being floating.

In yet another aspect of the present disclosure, a method for forming semiconductor devices is disclosed. The method includes forming a redistribution structure comprising a plurality of layers. Each of the plurality of layers comprises a power/ground plane embedded in a dielectric material, and wherein the power/ground plane encloses: a plurality of first conductive structures; and a plurality of second conductive structures collectively surrounding the plurality of first conductive structures. The method includes attaching the redistribution structure to a semiconductor die on a first side of the redistribution structure with a plurality of first connectors. The power/ground plane is configured to provide the semiconductor die with a supply voltage. The plurality of first conductive structures are each operatively coupled to the semiconductor die. The plurality of second conductive structures each have a floating voltage.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a redistribution structure comprising a plurality of layers, wherein each of the plurality of layers comprises a power/ground plane embedded in a dielectric material, and wherein the power/ground plane encloses a plurality of first conductive structures and a plurality of second conductive structures collectively surrounding the plurality of first conductive structures; and
attaching the redistribution structure to a first semiconductor die on a first side of the redistribution structure with a plurality of first connectors;
wherein the power/ground plane is configured to provide the first semiconductor die with a supply voltage, the plurality of first conductive structures are each operatively coupled to the semiconductor die, and the plurality of second conductive structures each have a floating voltage.

2. The method of claim 1, further comprising:
attaching the redistribution structure to a substrate on a second side of the redistribution structure with a plurality of second connectors, the second side being opposite to the first side.

3. The method of claim 2, wherein the redistribution structure is configured to rearrange a first pattern of the plurality of first connectors as a second pattern of the plurality of second connectors.

4. The method of claim 2, further comprising:
forming a plurality of third connectors on a first side of the substrate opposite to a second side of the substrate that faces the plurality of second connectors.

5. The method of claim 1, wherein a spacing between neighboring ones of the plurality of first conductive structures is equal to or greater than about 20 micrometers (μm).

6. The method of claim 1, wherein the plurality of second conductive structures are scattered around the plurality of first conductive structures.

7. The method of claim 1, wherein the power/ground plane further encloses a guard ring that partially surrounds the plurality of first conductive structures and the plurality of second conductive structures.

8. The method of claim 7, wherein the guard ring is either connected to or isolated from the power/ground plane.

9. The method of claim 1, wherein the power/ground plane further encloses a guard ring that fully surrounds the plurality of first conductive structures and the plurality of second conductive structures.

10. The method of claim 9, wherein the guard ring is either connected to or isolated from the power/ground plane.

11. A method for forming a semiconductor device, comprising:
forming a redistribution structure comprising a plurality of layers, wherein each of the plurality of layers comprises a power/ground plane embedded in a dielectric material, and wherein the power/ground plane encloses a plurality of first conductive structures and a plurality of second conductive structures collectively surrounding the plurality of first conductive structures;
attaching the redistribution structure to a first semiconductor die on a first side of the redistribution structure with a plurality of first connectors; and
attaching the redistribution structure to a substrate on a second side of the redistribution structure with a plurality of second connectors, the second side being opposite to the first side;
wherein the power/ground plane is configured to provide the first semiconductor die with a supply voltage, the plurality of first conductive structures are each operatively coupled to the semiconductor die, and the plurality of second conductive structures each have a floating voltage.

12. The method of claim 11, wherein the redistribution structure is configured to rearrange a first pattern of the plurality of first connectors as a second pattern of the plurality of second connectors.

13. The method of claim 11, wherein a spacing between neighboring ones of the plurality of first conductive structures is equal to or greater than about 20 micrometers (μm).

14. The method of claim 11, wherein the plurality of second conductive structures are scattered around the plurality of first conductive structures.

15. The method of claim 11, wherein the power/ground plane further encloses a guard ring that partially or fully surrounds the plurality of first conductive structures and the plurality of second conductive structures.

16. The method of claim 15, wherein the guard ring is either connected to or isolated from the power/ground plane.

17. A method for forming a semiconductor device, comprising:
forming a redistribution structure comprising a plurality of layers, wherein each of the plurality of layers comprises a power/ground plane embedded in a dielectric material, and wherein the power/ground plane encloses a plurality of first conductive structures and a plurality of second conductive structures collectively surrounding the plurality of first conductive structures;
attaching the redistribution structure to a first semiconductor die on a first side of the redistribution structure with a plurality of first connectors; and
attaching the redistribution structure to a substrate on a second side of the redistribution structure with a plurality of second connectors, the second side being opposite to the first side;
wherein the power/ground plane is configured to provide the first semiconductor die with a supply voltage, the plurality of first conductive structures are each operatively coupled to the semiconductor die and configured to route a signal, and the plurality of second conductive structures each have a floating voltage and formed as a dot scattered around the plurality of first conductive structures.

18. The method of claim 17, wherein the redistribution structure is configured to rearrange a first pattern of the plurality of first connectors as a second pattern of the plurality of second connectors.

19. The method of claim 17, wherein a spacing between neighboring ones of the plurality of first conductive structures is equal to or greater than about 20 micrometers (μm).

20. The method of claim 17, wherein the power/ground plane further encloses a guard ring that partially or fully surrounds the plurality of first conductive structures and the plurality of second conductive structures.
